(19) United States
(12) Patent Application Publication
(10) Pub. No.: US 2026/0227461 A1
(43) Pub. Date: Aug. 6, 2026

(54) Power Supply Device

(71) Applicant: Mitsubishi Electric Corporation, Chiyoda-ku, Tokyo (JP)

(72) Inventors: Kento TOYOTA, Chiyoda-ku, Tokyo (JP); Yoshikazu TSUNODA, Chiyoda-ku, Tokyo (JP); Koji NAKAJIMA, Chiyoda-ku, Tokyo (JP); Takashi KUMAGAI, Chiyoda-ku, Tokyo (JP)

(73) Assignee: Mitsubishi Electric Corporation, Chiyoda-ku, Tokyo (JP)

(21) Appl. No.: 19/148,199

(22) PCT Filed: Jan. 17, 2024
(86) PCT No.: PCT/JP2024/001126

§ 371 Date: Jul. 15, 2025

(30) Foreign Application Priority Data
Jan. 27, 2023 (JP) 2023-010873

(51) Int. Cl. G01R 31/56; G01R 31/382; H02M 1/00; H02M 1/088; H02M 1/14; H02M 1/34; H02M 3/335

(52) U.S. Cl. CPC G01R 31/56; G01R 31/382; H02M 1/088; H02M 1/143; H02M 1/34; H02M 1/0009; H02M 3/33515

(57) ABSTRACT

In a power supply device including a plurality of converters connected in parallel, in a determination mode, a lifespan determination unit stops an operation of a target converter to be subjected to lifespan determination, while keeping the other converters in operation, and determines whether the target converter has reached an end of life based on a degree of decrease in voltage caused by discharging of a smoothing capacitor of the target converter. When there is a deteriorated converter having reached the end of life in the determination mode, the lifespan determination unit shifts the operation mode to a restriction mode, the restriction mode being a mode of restricting an output of the deteriorated converter.

### TECHNICAL FIELD

The present disclosure relates to a power supply device.

### BACKGROUND ART

In recent years, there have been many demands for higher power, higher reliability and smaller size of a power supply device that supplies a direct current (DC) to a load. Particularly, there has been an increasing demand for higher power of a DC power supply device used for DC power feeding in a zero emission building (ZEB), a data center and the like.

As a method of achieving a larger current and a larger capacity of a power supply device, a method of connecting a plurality of converters in parallel is known (refer to, for example, Japanese Patent Laying-Open No. 2006-034047 (PTL 1)).

### CITATION LIST

### Patent Literature

PTL 1: Japanese Patent Laying-Open No. 2006-034047

### SUMMARY OF INVENTION

### Technical Problem

In a power supply device including converters connected in parallel, the entire power supply becomes inoperative when one of the converters fails. Therefore, the parallel connection of the converters requires replacement of a deteriorated converter before the converter fails, in order to prevent a stop of electric power supply.

The present disclosure has been made in view of the above-described problem and an object thereof is to provide, in a power supply device including converters connected in parallel, a method of checking a deterioration state of each converter before each converter fails.

### Solution to Problem

A power supply device according to an embodiment includes: a plurality of converters connected in parallel with each other between an input node and an output node; and a lifespan determination unit. The power supply device has a normal mode, a determination mode and a restriction mode as operation modes. In the determination mode, the lifespan determination unit stops an operation of a target converter to be subjected to lifespan determination, while keeping the other converters in operation, and determines whether the target converter has reached an end of life based on a degree of decrease in voltage caused by discharging of a smoothing capacitor of the target converter. When the lifespan determination unit determines in the determination mode that no converters have reached the end of life, the lifespan determination unit shifts the operation mode to the normal mode, the normal mode being a mode of operating the plurality of converters without output restriction. When there is a deteriorated converter having reached the end of life in the determination mode, the lifespan determination unit shifts the operation mode to the restriction mode, the restriction mode being a mode of restricting an output of the deteriorated converter.

### Advantageous Effects of Invention

According to the above-described embodiment, in the determination mode, the lifespan determination unit stops the operation of the target converter to be subjected to lifespan determination, while keeping the other converters in operation, and determines whether the target converter has reached the end of life based on the degree of decrease in voltage caused by discharging of the smoothing capacitor of the target converter. Therefore, in the power supply device including the converters connected in parallel, a deterioration state of each converter can be checked before each converter fails.

### BRIEF DESCRIPTION OF DRAWINGS

FIG. 1 is a block diagram showing an overall configuration of a power supply device according to a first embodiment.

FIG. 2 is a circuit diagram showing an exemplary internal configuration of a converter in FIG. 1.

FIG. 3 is a block diagram showing an exemplary configuration of a shunt regulator in FIG. 2.

FIG. 4 is a block diagram showing an exemplary configuration of a current control unit in FIG. 2.

FIG. 5 is a state transition diagram showing transition among operation modes of the power supply device.

FIG. 6 is a flowchart showing a procedure of lifespan determination by a lifespan determination unit.

FIG. 7 is a timing chart showing a temporal change in output current of each converter in a determination mode.

FIG. 8 is a diagram showing a discharge path of a smoothing capacitor on the secondary side of a transformer.

FIG. 9 is a diagram for illustrating a principle of lifespan determination of a converter.

FIG. 10 is a flowchart showing an operation of the lifespan determination unit in a restriction mode.

FIG. 11 is a timing chart showing a temporal change in output current of each converter in the restriction mode.

FIG. 12 is a circuit diagram showing an exemplary configuration of a flyback-type DC/DC converter that outputs a negative voltage.

FIG. 13 is a circuit diagram showing an exemplary configuration of a converter in a power supply device according to a second embodiment.

FIG. 14 is a diagram for illustrating an effect of a discharge circuit in FIG. 13.

FIG. 15 is a circuit diagram showing an exemplary configuration of a converter in a power supply device according to a third embodiment.

FIG. 16 is a flowchart showing a procedure of lifespan determination by a lifespan determination unit in a power supply device according to a fourth embodiment.

FIG. 17 is a diagram for illustrating a principle of lifespan determination of a converter in a power supply device according to a fourth embodiment.

FIG. 18 is a flowchart showing a procedure of lifespan determination by a lifespan determination unit in a power supply device according to a fifth embodiment.

FIG. 19 is a timing chart showing an operation of each converter constituting the power supply device according to the fifth embodiment.

FIG. 20 is a flowchart showing an operation of a lifespan determination unit in a restriction mode in a power supply device according to a sixth embodiment.

FIG. 21 is a timing chart showing a change in target value of an output voltage of each converter in the restriction mode in the power supply device according to the sixth embodiment.

FIG. 22 is a flowchart showing an operation of a lifespan determination unit in a restriction mode in a power supply device according to a seventh embodiment.

FIG. 23 is a timing chart showing a change in target value of the output voltage of each converter in the restriction mode in the power supply device according to the seventh embodiment.

FIG. 24 is a diagram for illustrating a method of two-level lifespan determination.

FIG. 25 is a flowchart showing a procedure of lifespan determination when a threshold value is set to two levels.

FIG. 26 is a flowchart showing an operation procedure in a maintenance mode.

FIG. 27 is a diagram for illustrating a lifespan determination threshold value in the maintenance mode.

FIG. 28 is a circuit diagram showing an exemplary configuration of a converter in a power supply device according to an eleventh embodiment.

FIG. 29 is a diagram showing a relationship between an ambient temperature and a frequency of lifespan determination of a smoothing electrolytic capacitor.

FIG. 30 is a flowchart showing a procedure of changing a frequency of execution of lifespan determination in accordance with the ambient temperature of the smoothing electrolytic capacitor.

### DESCRIPTION OF EMBODIMENTS

Hereinafter, embodiments will be described in detail with reference to the drawings. The same or corresponding portions are denoted by the same reference characters and description thereof will not be repeated.

### First Embodiment

### [Overall Configuration of Power Supply Device 1]

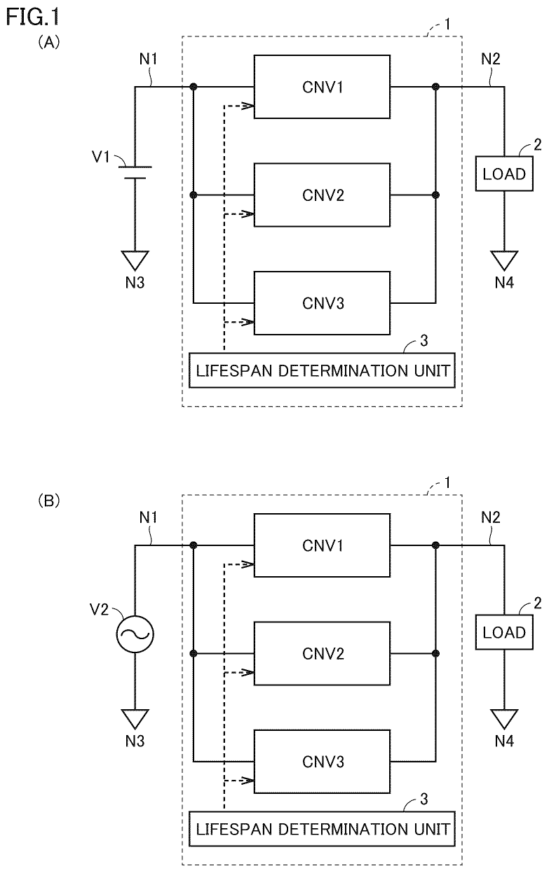

FIG. 1 is a block diagram showing an overall configuration of a power supply device 1 according to a first embodiment. FIG. 1(A) shows a block diagram of power supply device 1 at DC (direct current) input and FIG. 1(B) shows a block diagram of power supply device 1 at AC (alternating current) input.

Power supply device 1 includes a plurality of converters CNV1 to CNV3 (hereinafter denoted as converter CNV when the plurality of converters CNV1 to CNV3 are collectively referred to or any one of them is referred to) and a lifespan determination unit 3. FIG. 1 shows three converters CNVs as an example. However, any number of converters CNVs may be connected in parallel depending on a required output voltage, as long as two or more converters CNVs are connected in parallel, and the number of converters CNVs is not particularly limited.

Converters CNV1 to CNV3 are connected in parallel with each other between an input node N1 and an output node N2. In FIG. 1(A), an external DC power supply V1 is connected between input node N1 and a ground node N3 on the input side. In FIG. 1(B), an external AC power supply V2 is connected between input node N1 and ground node N3 on the input side. On the other hand, in FIGS. 1(A) and 1(B), a load 2 is connected between output node N2 and a ground node N4 on the output side.

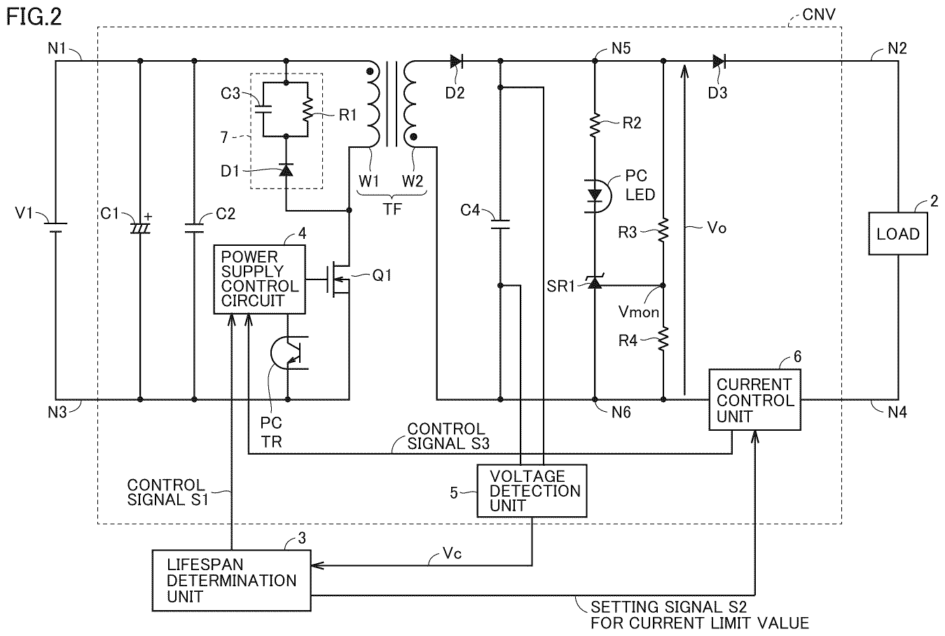

Each converter CNV converts DC power or AC power into DC power. A more detailed exemplary configuration of converter CNV will be described below with reference to FIG. 2.

Load 2 is a DC electric device having a medium capacity or a large capacity. Examples of load 2 include a lighting device, an inverter device for driving an AC motor, and the like.

Lifespan determination unit 3 is connected to each converter CNV by a signal line to control an operation of each converter CNV in accordance with a control signal (S1 in FIG. 2) and determine a lifespan of each converter CNV. Hereinafter, converter CNV to be subjected to lifespan determination will be referred to as “target converter” and converter CNV not to be subjected to lifespan determination will be referred to as “non-target converter”.

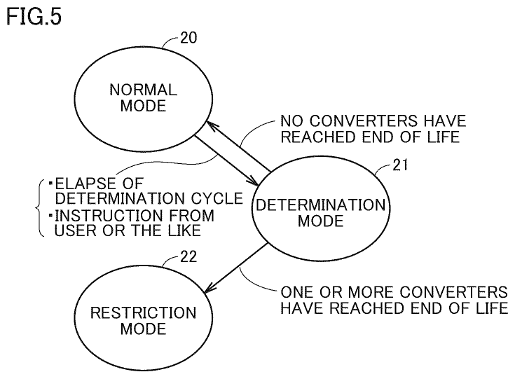

A detailed method of lifespan determination will be described below with reference to FIGS. 5 to 12. In the present disclosure, a state in which converter CNV has reached the end of “life” refers to a state in which converter CNV has entered a wear failure period after an initial failure period and an accidental failure period, not a state immediately before converter CNV stops operating due to a failure. Therefore, converter CNV having reached the end of life can continue to operate for approximately several hundreds of hours until converter CNV actually fails and stops operating.

Lifespan determination unit 3 is configured based on a computer including a central processing unit (CPU) and a memory. Alternatively, at least a part of lifespan determination unit 3 may be configured by a programmable logic device (PLD) such as a field programmable gate array (FPGA) and/or a dedicated circuit such as an application specific integrated circuit (ASIC).

### [Exemplary Internal Configuration of Converter CNV]

FIG. 2 is a circuit diagram showing an exemplary internal configuration of converter CNV in FIG. 1. FIG. 2 shows a flyback-type DC/DC converter as an example of converter CNV. Instead of the flyback-type DC/DC converter, a forward-type DC/DC converter or a DC/DC converter of another type may be used. Converter CNV is not limited to an insulated DC/DC converter (or switching power supply) and may be a non-insulated DC/DC converter (or switching power supply).

Referring to FIG. 2, converter CNV includes a transformer TF and further includes, as components on the primary side of transformer TF, a power supply smoothing capacitor C1, a main circuit capacitor C2, a semiconductor switching element Q1 (also referred to as a first switching element), a power supply control circuit 4, and a snubber circuit 7. Converter CNV further includes, as components on the secondary side of transformer TF, diodes D2 and D3, resistance elements R2, R3 and R4, a shunt regulator SR1, a smoothing capacitor C4, a voltage detection unit 5, and a current control unit 6. Converter CNV further includes a photocoupler PC for feeding back information about the output voltage from the secondary side to the primary side of transformer TF. FIG. 2 shows, in a separated manner, a light emitting diode (LED) and a phototransistor TR that constitute the photocoupler.

Connections between and functions of the components of converter CNV in FIG. 2 will be described below. The primary side of transformer TF will be described first.

Power supply smoothing capacitor C1 and main circuit capacitor C2 are connected in parallel with each other between input node N1 and ground node N3 on the input side. Power supply smoothing capacitor C1 is provided for noise absorption and stable operation of converter CNV. Main circuit capacitor C2 is provided to absorb a ripple and noise produced during switching of semiconductor switching element Q1.

A primary winding W1 of transformer TF and semiconductor switching element Q1 are connected in series with each other between input node N1 and ground node N3 and in parallel with each of power supply smoothing capacitor C1 and main circuit capacitor C2. As described below, switching of semiconductor switching element Q1 is controlled by a gate signal supplied from power supply control circuit 4. In response to switching of semiconductor switching element Q1, energy is stored in transformer TF (or a reactor) and electric power is transmitted from the primary side to the secondary side of transformer TF.

Snubber circuit 7 is connected in parallel with primary winding W1 of transformer TF. Snubber circuit 7 suppresses a surge voltage generated by switching of semiconductor switching element Q1. Thus, switching noise during turn-off of semiconductor switching element Q1 can be reduced. More specifically, snubber circuit 7 includes a capacitor C3, a resistance element R1 and a diode D1. Capacitor C3 and resistance element R1 are connected in parallel with each other between a first end of primary winding W1 of transformer TF and a cathode of diode D1. An anode of diode D1 is connected to a second end of primary winding W1 of transformer TF.

Power supply control circuit 4 monitors and controls an overall operation of converter CNV. Specifically, power supply control circuit 4 controls an output voltage Vo and an output current Io by adjusting a duty factor of a pulse width modulation (PWM) signal to be supplied to a gate of semiconductor switching element Q1. Furthermore, power supply control circuit 4 has an overvoltage protection function and an overcurrent protection function.

Next, the secondary side of transformer TF will be described. As shown in FIG. 2, an intermediate node N5 is provided between a first end (high-potential side) of a secondary winding W2 of transformer TF and output node N2, and an intermediate node N6 is provided between a second end (low-potential side) of secondary winding W2 of transformer TF and ground node N4. In FIG. 2, intermediate node N6 on the low-potential side is directly connected to the second end of secondary winding W2 of transformer TF.

An anode of diode D2 is connected to the first end (high-potential side) of secondary winding W2 of transformer TF, and a cathode of diode D2 is connected to intermediate node N5. Diode D2 is provided to rectify the AC power transmitted to the secondary side of transformer TF.

Smoothing capacitor C4 is connected between intermediate node N5 on the high-potential side and intermediate node N6 on the low-potential side. Smoothing capacitor C4 smooths the voltage rectified by diode D2. Thus, DC output voltage Vo is generated between both ends of smoothing capacitor C4.

Resistance element R2, the LED of photocoupler PC, and shunt regulator SR1 are connected in this order in series with each other between intermediate nodes N5 and N6 and in parallel with smoothing capacitor C4. In addition, resistance elements R3 and R4 are connected in this order in series with each other between intermediate nodes N5 and N6 and in parallel with smoothing capacitor C4. A voltage at a connection node of resistance elements R3 and R4 is taken into shunt regulator SR1 as a monitor voltage Vmon for monitoring output voltage Vo.

Shunt regulator SR1 maintains output voltage Vo constant by increasing a cathode current flowing through shunt regulator SR1 when output voltage Vo increases, and decreasing the cathode current flowing through shunt regulator SR1 when output voltage Vo decreases.

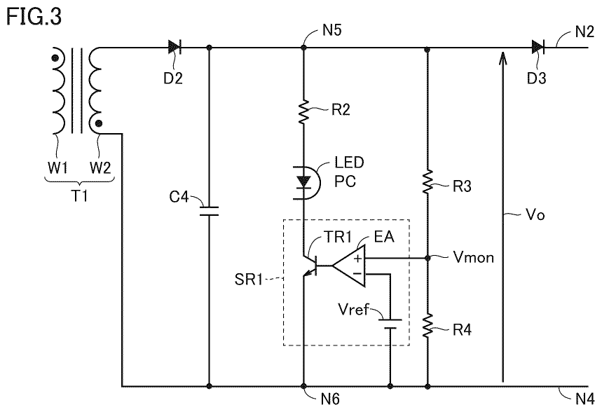

FIG. 3 is a block diagram showing an exemplary configuration of the shunt regulator in FIG. 2. Shunt regulator SR1 in FIG. 3 includes an error amplifier EA, a voltage source that generates a reference voltage Vref, and an NPN transistor TR1. FIG. 3 also shows the other components on the secondary side of transformer TF of converter CNV.

As shown in FIG. 3, resistance element R2, the LED of photocoupler PC, and NPN transistor TR1 are connected in this order in series with each other between intermediate nodes N5 and N6 and in parallel with smoothing capacitor C4. Monitor voltage Vmon is input to a non-inversion input node of error amplifier EA, and reference voltage Vref is input to an inversion input node of error amplifier EA. An output node of error amplifier EA is connected to a base of NPN transistor TR1.

According to the above-described configuration of shunt regulator SR1, a current corresponding to a difference between monitor voltage Vmon and reference voltage Vref flows between a collector and an emitter of NPN transistor TR1 (i.e., between a cathode and an anode of shunt regulator SR1). In accordance with this current, the LED of photocoupler PC emits light and the light emitted by the LED is received by phototransistor TR of photocoupler PC. Thus, a current corresponding to an amount of the received light flows between a collector and an emitter of phototransistor TR. As a result, the information about the value of output voltage Vo can be transmitted to power supply control circuit 4.

Referring again to FIG. 2, diode D3 is provided to prevent inflow of a current from the other non-target converters during lifespan determination of the target converter. Specifically, the anode of diode D3 is connected to intermediate node N5 and the cathode of diode D3 is connected to output node N2. Therefore, the cathode of diode D3 is also connected to the cathodes of diodes D3 of the other converters CNVs connected to output node N2. Diode D3 is provided to prevent the current from flowing into target converter CNV to be subjected to lifespan determination from non-target converters CNVs not to be subjected to lifespan determination (i.e., to prevent a backflow).

Voltage detection unit 5 is connected to both ends of smoothing capacitor C4 to detect a voltage Vc (also referred to as a capacitor voltage Vc) stored in smoothing capacitor C4. Voltage detection unit 5 transmits detected capacitor voltage Vc to lifespan determination unit 3.

Current control unit 6 is connected between intermediate node N6 on the low-potential side and ground node N4 on the secondary side. Current control unit 6 detects output current Io of converter CNV, and outputs a control signal S3 for decreasing output current Io to power supply control circuit 4 when output current Io exceeds a current limit value IL.

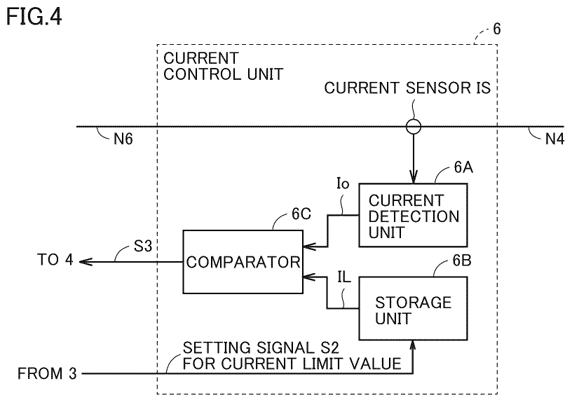

FIG. 4 is a block diagram showing an exemplary configuration of current control unit 6 in FIG. 2. Referring to FIG. 4, current control unit 6 includes a current sensor IS, a current detection unit 6A, a storage unit 6B, and a comparator 6C. Current control unit 6 is configured by, for example, a PLD such as an FPGA and/or a dedicated circuit such as an ASIC.

Current detection unit 6A detects output current Io of converter CNV through current sensor IS. Storage unit 6B stores current limit value IL set in accordance with a setting signal S2 from lifespan determination unit 3. Comparator 6C compares detected output current Io with set current limit value IL, and when output current Io exceeds current limit value IL, comparator 6C makes control signal S3 active. When control signal S3 is made active, power supply control circuit 4 decreases output current Io by adjusting a duty factor of semiconductor switching element Q1.

### [Description of Operation Modes]

FIG. 5 is a state transition diagram showing transition among operation modes of power supply device 1. The operation modes of power supply device 1 include a normal mode 20, a determination mode 21 and a restriction mode 22.

Normal mode 20 is an operation mode when each converter CNV is supplying electric power to load 2 within a preset current range for a normal operation. When lifespan determination of each converter CNV is not in execution, power supply device 1 is operating in normal mode 20. Lifespan determination unit 3 shifts the operation mode from normal mode 20 to determination mode 21 every predetermined determination cycle (i.e., when the determination cycle has elapsed) or based on a command from a user, a serviceman or the like. The shift from normal mode 20 to determination mode 21 may be implemented not only by the elapse of the determination cycle but also by the user or the serviceman pressing a manual switch provided in power supply device 1, for example.

Determination mode 21 is an operation mode when lifespan determination unit 3 is executing the lifespan determination of each converter CNV. In determination mode 21, lifespan determination unit 3 sequentially executes the lifespan determination of each converter CNV. When the lifespan determination of all of the converters is completed, the operation mode is returned to normal mode 20 or is shifted to restriction mode 22. Specifically, when there are not any converters determined as having reached the end of life (hereinafter referred to as “deteriorated converter”), lifespan determination unit 3 returns the operation mode to normal mode 20. On the other hand, when there are one or more deteriorated converters, lifespan determination unit 3 shifts the operation mode from determination mode 21 to restriction mode 22.

Restriction mode 22 is an operation mode in which, when one or more converters CNVs have reached the end of life as a result of the lifespan determination, output currents Io of these deteriorated converters are restricted. Lifespan determination unit 3 suppresses a current limit value of the deteriorated converter to be low and increases a current limit value of converter CNV determined as not having reached the end of life as a result of the lifespan determination (hereinafter referred to as “normal converter”).

### [Operation in Determination Mode]

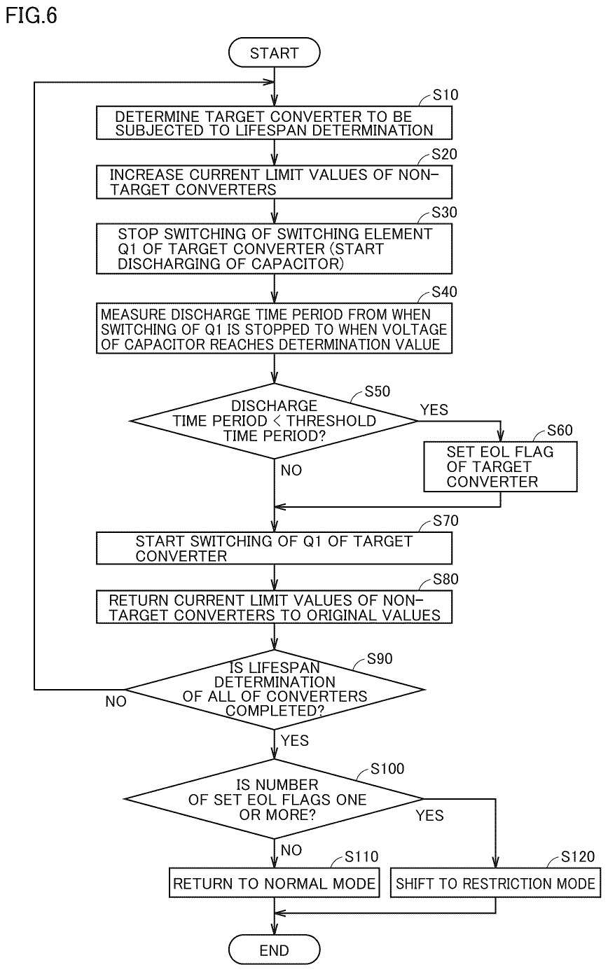

Next, an operation of lifespan determination unit 3 of power supply device 1 in the determination mode will be described with reference to FIGS. 6 to 9. FIG. 6 is a flowchart showing a procedure of lifespan determination by the lifespan determination unit.

In step S10 in FIG. 6, lifespan determination unit 3 determines the target converter to be subjected to lifespan determination, of converters CNVs included in power supply device 1. The lifespan determination is sequentially executed on all of converters CNVs and the order of execution is not particularly limited. In the example in FIG. 1, the lifespan determination is executed on converter CNV3, converter CNV2 and converter CNV1 in this order.

In next step S20, lifespan determination unit 3 transmits setting signal S2 to current control units 6 of the non-target converters other than the target converter so as to increase the current limit values of the non-target converters to be higher than setting values in the normal mode. Since the current limit values of the non-target converters are increased only during the determination mode, there is no risk of deteriorating the non-target converters. In addition, in the case of a light load in which a load current in normal times is small, increasing the current limit values is not particularly necessary.

In next step S30, lifespan determination unit 3 transmits control signal S1 for stopping switching of semiconductor switching element Q1 of the target converter to power supply control circuit 4. As a result, transmission of the electric power from the primary side to the secondary side of transformer TF stops, and thus, output current Io of target converter CNV becomes zero. Furthermore, when transmission of the electric power from the primary side to the secondary side of transformer TF stops, discharging of smoothing capacitor C4 on the secondary side of transformer TF is started.

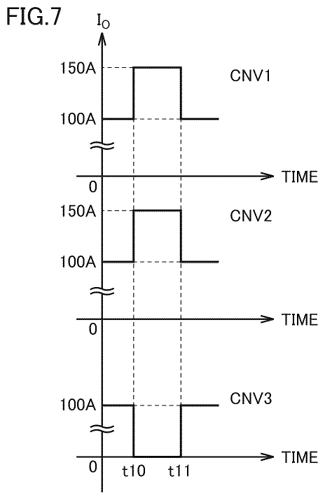

FIG. 7 is a timing chart showing a temporal change in output current of each converter in the determination mode. In FIG. 7, a time period before time t10 corresponds to the normal mode, and a time period from time t10 to time t11 corresponds to a time period during which the lifespan determination of target converter CNV3 is executed in the determination mode.

In the normal mode before time t10, a current of 100 A is output from each of converters CNV1 to CNV3 to load 2. Therefore, output current Io of 300 A is supplied to load 2 in power supply device 1 as a whole.

When the lifespan determination of converter CNV3 is started at time t10 or later, an operation of target converter CNV3 is stopped. As a result, output current Io of converter CNV3 becomes zero. In contrast, output current Io of each of non-target converters CNV1 and CNV2 is increased to 150 A. As a result, output current Io supplied from the whole of power supply device 1 to load 2 in the determination mode is 300 A, which can be equal to output current Io in the normal mode.

When the current limit value of each of the non-target converters in the normal mode is less than 150 A, it is necessary to increase the current limit value of each of the non-target converters in the determination mode to 150 A or more. Although the case in which sharing of output current Io by the respective converters in the normal mode is equal has been described above, the sharing may be unequal.

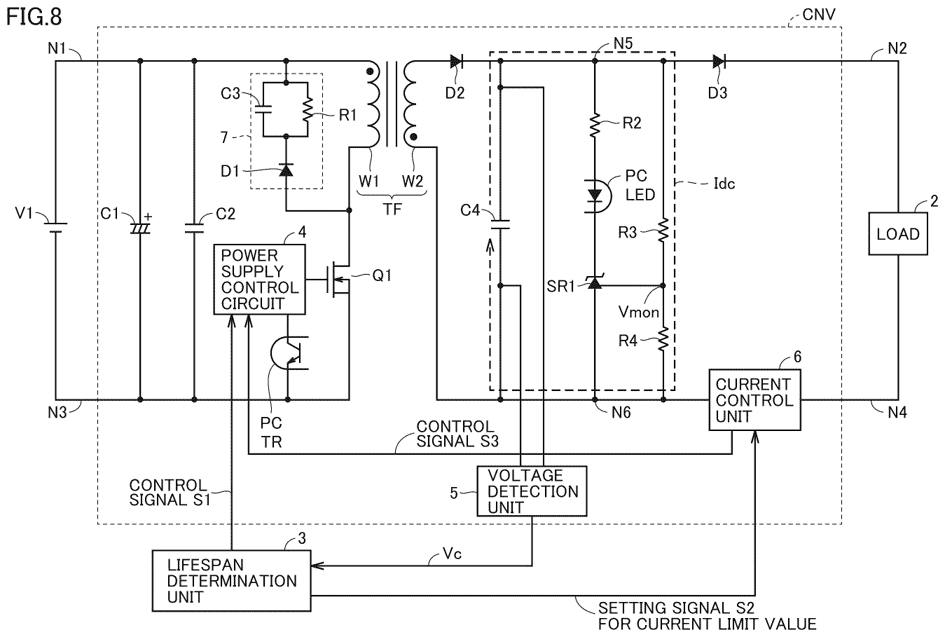

FIG. 8 is a diagram showing a discharge path of smoothing capacitor C4 on the secondary side of transformer TF. In FIG. 8, when switching of semiconductor switching element Q1 is stopped, discharging of smoothing capacitor C4 on the secondary side of transformer TF is started. A discharge path Idc from smoothing capacitor C4 is a path from a positive electrode of smoothing capacitor C4 through resistance element R3 and resistance element R4 back to a negative electrode of smoothing capacitor C4. A voltage between both electrodes of smoothing capacitor C4 is monitored by voltage detection unit 5.

Referring back to FIG. 6, in next step S40, lifespan determination unit 3 measures a discharge time period from when discharging of smoothing capacitor C4 is started by stopping switching of semiconductor switching element Q1 to when the voltage of smoothing capacitor C4 reaches a determination value. A counter built into lifespan determination unit 3 is, for example, used to measure the discharge time period. When the discharge time period is shorter than a threshold time period (YES in step S50), lifespan determination unit 3 determines that the target converter has reached the end of life, and sets an EOL (End Of Life) flag of the target converter (step S60). On the other hand, when the discharge time period is equal to or longer than the threshold time period (NO in step S50), lifespan determination unit 3 determines that the target converter has not yet reached the end of life, and does not set the EOL flag.

The threshold time period is calculated in advance based on the properties of smoothing capacitor C4. As an example, an upper limit value of an amount of voltage ripple that is acceptable in a system is set and a lower limit value of a required capacitance is calculated from the upper limit value of the amount of voltage ripple. Then, a lower limit value of the discharge time period is derived from the lower limit value of the capacitance, and the threshold value of the discharge time period is determined in consideration of a time margin until an actual failure occurs.

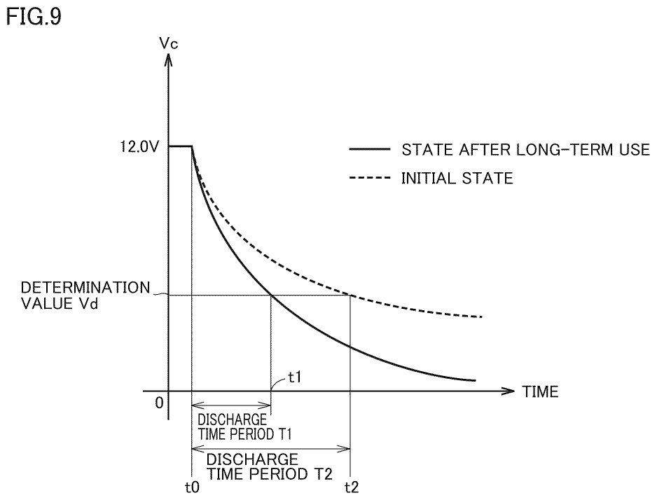

FIG. 9 is a diagram for illustrating a principle of lifespan determination of the converter. FIG. 9 shows an exemplary discharge curve in an initial state of the converter product (broken line) and an exemplary discharge curve in a state after long-term use (solid line). Let us assume that a rated value of voltage Vc of smoothing capacitor C4 in the normal mode is 12.0 V.

At time t0 in FIG. 9, lifespan determination unit 3 switches control signal S1 to be transmitted to power supply control circuit 4, thereby stopping switching of semiconductor switching element Q1.

Lifespan determination unit 3 measures a time period to when voltage Vc of smoothing capacitor C4 reaches a determination value Vd. In the initial state of the converter product, voltage Vc reaches determination value Vd at time t2, and thus, the discharge time period is T2. On the other hand, in the state after long-term use, voltage Vc reaches determination value Vd at time t1, and thus, the discharge time period is T1, which is shorter than discharge time period T2 in the initial state. When the discharge time period is shorter than the threshold time period, lifespan determination unit 3 determines that the target converter has reached the end of life.

Referring back to FIG. 6, when the determination as to whether the target converter has reached the end of life is completed (steps S50 and S60), lifespan determination unit 3 transmits control signal S1 for starting switching of semiconductor switching element Q1 to power supply control circuit 4 in next step S70. As a result, the target converter starts a power conversion operation. As shown at time t11 or later in FIG. 7, the target converter starts to output the current and output current Io of each of the non-target converters returns to the original value.

In next step S80, lifespan determination unit 3 returns current limit values IL stored in current control units 6 of the non-target converters to the original values.

In this way, the lifespan determination of the currently set target converter is completed. When the lifespan determination of all of converters CNVs is not completed (NO in step S90), lifespan determination unit 3 returns the process to step S10, sets converter CNV that is not yet subjected to lifespan determination as a target converter, and executes the lifespan determination of this converter (steps S20 to S80).

When the lifespan determination of all of converters CNVs is completed (YES in step S90), lifespan determination unit 3 checks in next step S100 whether the number of the set EOL flags is one or more. When no EOL flag is set (NO in step S100), lifespan determination unit 3 returns the operation mode to the normal mode (step S110). When one or more EOL flags are set (YES in step S100), lifespan determination unit 3 shifts the operation mode to the restriction mode (step S120).

### [Operation in Restriction Mode]

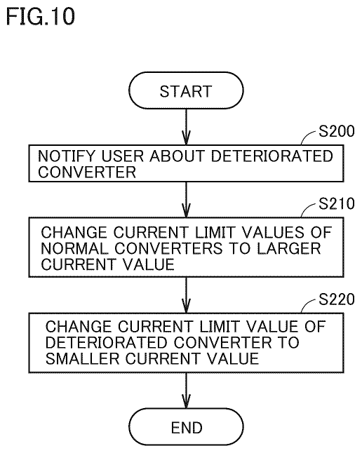

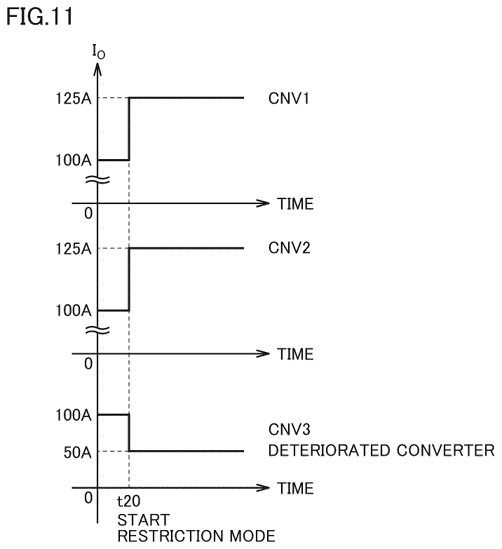

Next, an operation of lifespan determination unit 3 of power supply device 1 in the restriction mode will be described with reference to FIGS. 10 and 11.

FIG. 10 is a flowchart showing the operation of the lifespan determination unit in the restriction mode. Referring to FIG. 10, in step S200, lifespan determination unit 3 notifies the user about the deteriorated converter determined as having reached the end of life in the determination mode. For example, lifespan determination unit 3 causes the deteriorated converter to issue an alarm, or causes the deteriorated converter to light an abnormality lamp.

In next step S210, lifespan determination unit 3 transmits setting signal S2 to current control units 6 of the normal converters so as to change current limit values IL of the normal converters to larger current values.

In next step S220, lifespan determination unit 3 transmits setting signal S2 to current control unit 6 of the deteriorated converter so as to change current limit value IL of the deteriorated converter to a smaller current value. The restriction mode is continued until the deteriorated converter is replaced.

FIG. 11 is a timing chart showing a temporal change in output current of each converter in the restriction mode. Let us assume that in the configuration of power supply device 1 in FIG. 1, converters CNV1 and CNV2 are normal converters and converter CNV3 is a deteriorated converter as a result of the lifespan determination in the determination mode.

At time t20, the restriction mode is started. In a state before time t20, when any one of converters CNVs is not being subjected to lifespan determination, the current of 100 A is output from each of converters CNV1 to CNV3 to load 2 and output current Io of 300 A is supplied to load 2 in power supply device 1 as a whole.

When the restriction mode is started, current limit values IL of normal converters CNV1 and CNV2 are increased from 100 A to 125 A and current limit value IL of deteriorated converter CNV3 is decreased from 100 A to 50 A. As a result, output current Io of each of normal converters CNV1 and CNV2 increases from 100 A to 125A and output current Io of deteriorated converter CNV3 decreases from 100 A to 50 A. Total output current Io supplied to load 2 is 300 A, which is the same as that before the restriction mode is started.

Current limit values IL of normal converters CNV1 and CNV2 are increased only in the case of a high load in which the total current supplied to load 2 is large, and increasing current limit values IL of normal converters CNV1 and CNV2 is not necessary in the case of a low load in which the total current supplied to load 2 is small.

The restriction mode is continued until deteriorated converter CNV3 is replaced. As described above, by restricting output current Io of deteriorated converter CNV3, the lifespan of deteriorated converter CNV3 can be prolonged until deteriorated converter CNV3 is replaced.

### EFFECTS OF FIRST EMBODIMENT

Power supply device 1 according to the first embodiment provides the following effects. First, the operation mode is periodically shifted to the determination mode and the deterioration state of the capacitor built into each converter CNV is determined in the determination mode based on the discharge time period of the capacitor. Thus, the user can be urged to replace the deteriorated converter by the issuance of the alarm or the like, before the deteriorated converter fails completely and the power supply device stops.

In addition, when the deteriorated converter is found, the operation mode is shifted to the restriction mode and output current Io of the deteriorated converter is restricted in the restriction mode. Thus, the lifespan of the deteriorated converter can be prolonged until the deteriorated converter is replaced.

In the determination mode, the operation of the target converter to be subjected to lifespan determination is stopped. Since the current output of the target converter is borne by the non-target converters not to be subjected to lifespan determination, output current Io of power supply device 1 as a whole does not change. Therefore, the lifespan determination of the target converter can be executed without stopping the operation of power supply device 1 and without any influence on load 2.

In addition, when the lifespan determination of the target converter is executed in the determination mode, the operation of the target converter is stopped, and thus, there is no longer an influence of switching noise or the like produced by the target converter itself. Therefore, stable and highly-accurate lifespan determination can be executed.

### [First Modification]

The method of lifespan determination in the first embodiment is applicable not only to the case in which the output of the power supply device is a positive voltage but also to the case in which the output of the power supply device is a negative voltage.

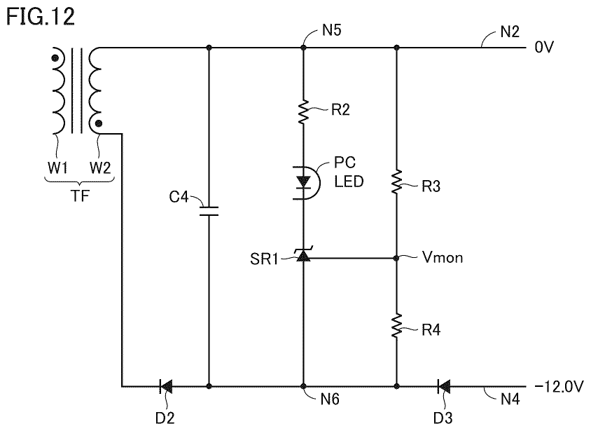

FIG. 12 is a circuit diagram showing an exemplary configuration of a flyback-type DC/DC converter that outputs a negative voltage. FIG. 12 shows a configuration on the secondary side of transformer TF. In FIG. 12, the portions corresponding to the flyback-type DC/DC converter that outputs the positive voltage in FIG. 2 are denoted by the same reference characters. In FIG. 12, diode D2 for rectification and diode D3 for backflow prevention are disposed on the negative voltage side. Since FIG. 12 is otherwise the same as FIG. 2, description will not be repeated.

### [Second Modification]

The method of lifespan determination in the first embodiment is applicable not only to the insulated DC/DC converter shown in FIG. 2 but also to a non-insulated DC/DC converter. In the case of the non-insulated DC/DC converter, it is necessary to separate a smoothing capacitor for measuring a discharge time period from an input-side DC power supply when switching of a semiconductor switching element is stopped for lifespan determination. For example, in the case of a step-down chopper and a step-up/step-down chopper, a semiconductor switching element may be switched to an open state at the time of lifespan determination. In the case of a step-up chopper, a switching element for synchronous rectification may be provided instead of the diode for rectification, and this switching element for synchronous rectification may be switched to an open state at the time of lifespan determination.

### Second Embodiment

### Characteristics of Second Embodiment

As described with reference to FIG. 8, in converter CNV in the first embodiment, smoothing capacitor C4 is discharged by using resistance elements R3 and R4 for monitoring output voltage Vo. Converter CNV in a second embodiment includes a dedicated circuit for discharging. This makes it possible to reduce the discharge time period. The following provides a detailed description with reference to the drawings.

### [Exemplary Internal Configuration of Converter]

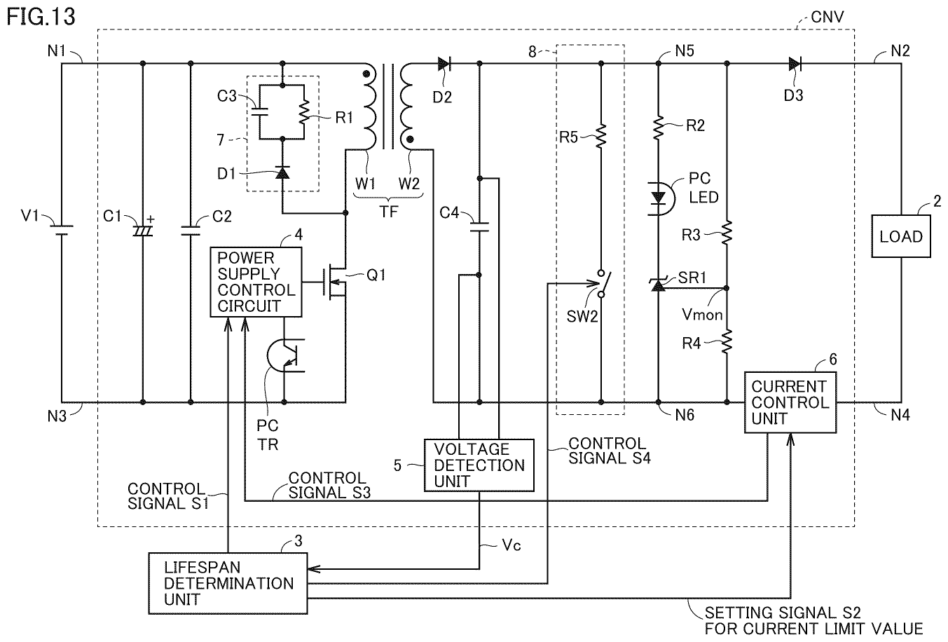

FIG. 13 is a circuit diagram showing an exemplary configuration of a converter in a power supply device according to the second embodiment.

Converter CNV in FIG. 13 is different from converter CNV in FIG. 2 in that converter CNV in FIG. 13 further includes a discharge circuit 8 provided between intermediate node N5 on the high potential side and intermediate node N6 on the low potential side in parallel with smoothing capacitor C4. Discharge circuit 8 includes a resistance element R5 and a semiconductor switching element SW2 connected in series with each other between intermediate nodes N5 and N6.

Lifespan determination unit 3 outputs a control signal S4 that controls opening and closing of semiconductor switching element SW2. When the lifespan determination of converter CNV is not in execution, semiconductor switching element SW2 is controlled to an open state. When lifespan determination unit 3 stops switching of semiconductor switching element Q1 to start the lifespan determination of converter CNV (step S30 in FIG. 6), lifespan determination unit 3 switches semiconductor switching element SW2 from the open state to a closed state. When lifespan determination unit 3 starts switching of semiconductor switching element Q1 to end the lifespan determination of converter CNV (step S70 in FIG. 6), lifespan determination unit 3 switches semiconductor switching element SW2 from the closed state to the open state.

Since FIG. 13 is otherwise the same as FIG. 2, the same or corresponding portions are denoted by the same reference characters and description will not be repeated.

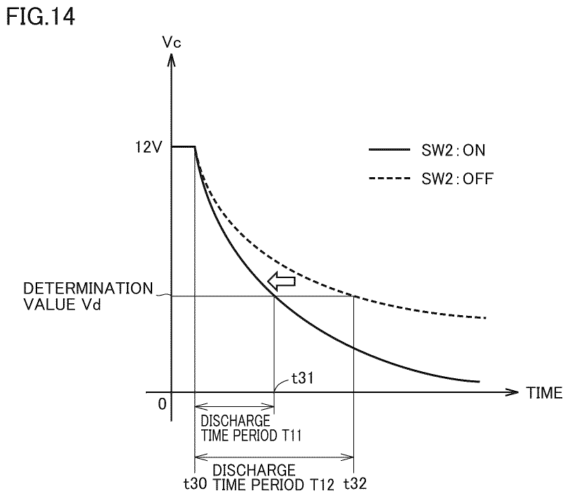

FIG. 14 is a diagram for illustrating an effect of the discharge circuit in FIG. 13. FIG. 14 shows a temporal change in voltage Vc of smoothing capacitor C4 during lifespan determination of converter CNV.

Referring to FIG. 14, at time t30, switching of semiconductor switching element Q1 is stopped for the lifespan determination of converter CNV. As a result, discharging of smoothing capacitor C4 is started.

A curve indicated by a broken line in FIG. 14 shows a discharge curve of smoothing capacitor C4 when semiconductor switching element SW2 is maintained in an OFF state. A discharge time period T12 from time t30 to time t32 at which voltage value Vc of smoothing capacitor C4 decreases to determination value Vd is measured. As described with reference to FIG. 8, a resistance value of a discharge path in this case is a serial composite resistance of resistance element R3 and resistance element R4.

A curve indicated by a solid line in FIG. 14 shows a discharge curve of smoothing capacitor C4 when semiconductor switching element SW2 is switched from the OFF state to an ON state at time t30. Since a discharge path in this case includes a path through resistance elements R3 and R4 and a path through resistance element R5 in parallel with the path, a composite resistance thereof is smaller than the above-described composite resistance of only resistance elements R3 and R4. Therefore, a discharge time period T11 from time t30 to time t31 at which voltage value Vc of smoothing capacitor C4 decreases to determination value Vd is shorter than above-described discharge time period T12.

### Effects of Second Embodiment

As described above, in the power supply device according to the second embodiment, discharging of smoothing capacitor C4 can be accelerated when the operation of the target converter is stopped for the lifespan determination. Therefore, the lifespan determination can be executed in a shorter time than in the first embodiment. Since semiconductor switching element SW2 of discharge circuit 8 is maintained in the open state in the normal mode and in the restriction mode, the operation of converter CNV in these operation modes is not affected.

### Third Embodiment

### Characteristics of Third Embodiment

In converter CNV shown in FIG. 2, diode D3 for backflow prevention is provided between intermediate node N5 on the high potential side and output node N2. In converter CNV provided in a power supply device according to a third embodiment, a semiconductor switching element is provided instead of diode D3. The third embodiment can be combined with the second embodiment.

### [Exemplary Internal Configuration of Converter]

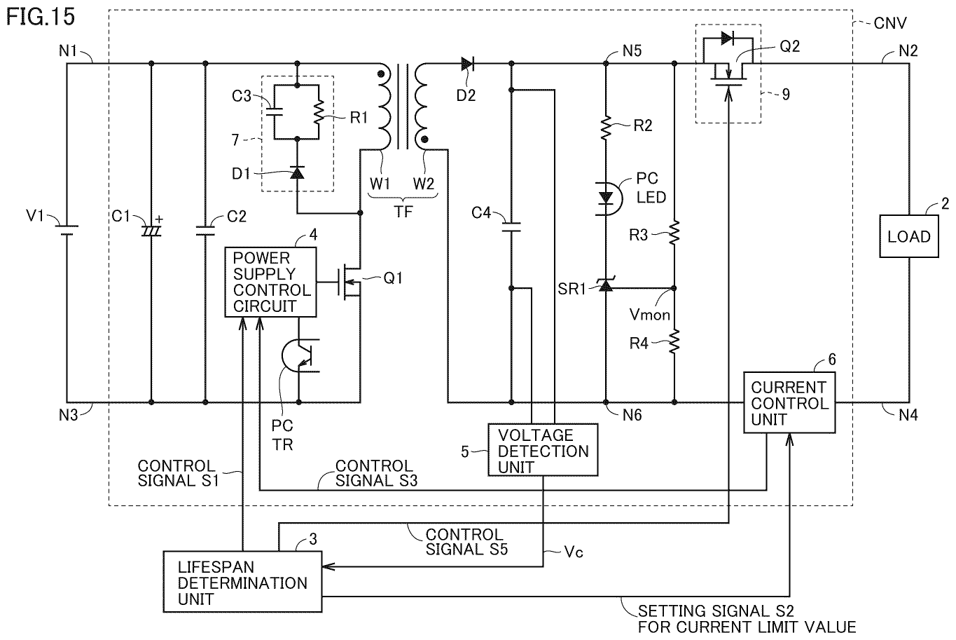

FIG. 15 is a circuit diagram showing an exemplary configuration of the converter in the power supply device according to the third embodiment.

Converter CNV in FIG. 15 includes a semiconductor switching element 9 (also referred to as a second switching element) instead of diode D3 for backflow prevention in FIG. 2. Opening and closing of semiconductor switching element 9 are controlled by a control signal S5 output from lifespan determination unit 3.

Specifically, in FIG. 15, an N-channel metal-oxide-semiconductor field effect transistor (MOSFET) Q2 is provided as semiconductor switching element 9. A source of N-channel MOSFET Q2 is connected to intermediate node N5 on the high potential side, and a drain of N-channel MOSFET Q2 is connected to output node N2. That is, N-channel MOSFET Q2 is connected such that a direction from intermediate node N5 to output node N2 corresponds to a forward direction of a parasitic diode of N-channel MOSFET Q2.

Instead of N-channel MOSFET Q2, a P-channel MOSFET may be used. In this case, a drain of the P-channel MOSFET is connected to intermediate node N5 on the high potential side, and a source of the P-channel MOSFET is connected to output node N2. That is, the P-channel MOSFET is connected such that a direction from intermediate node N5 to output node N2 corresponds to a forward direction of a parasitic diode of the P-channel MOSFET.

When there is a desire for ensuring a larger amount of conduction current, a plurality of MOSFETs may be connected in parallel. When there is a desire for ensuring a larger withstand voltage for a reverse voltage, a plurality of MOSFETs may be connected in series.

Lifespan determination unit 3 outputs control signal S5 that controls opening and closing of semiconductor switching element 9. When the lifespan determination of converter CNV is not in execution, semiconductor switching element 9 is controlled to a closed state. When lifespan determination unit 3 stops switching of semiconductor switching element Q1 to start the lifespan determination of converter CNV (step S30 in FIG. 6), lifespan determination unit 3 switches semiconductor switching element 9 from the closed state to an open state. When lifespan determination unit 3 starts switching of semiconductor switching element Q1 to end the lifespan determination of converter CNV (step S70 in FIG. 6), lifespan determination unit 3 switches semiconductor switching element 9 from the open state to the closed state.

Since FIG. 15 is otherwise the same as FIG. 2, the same or corresponding portions are denoted by the same reference characters and description will not be repeated.

### Effects of Third Embodiment

Since diode D3 for backflow prevention is used in the first embodiment, a forward voltage of diode D3 is as large as about 1 V and a product of a conduction current and the forward voltage of diode D3 is a loss of the diode. Therefore, the loss of diode D3 is not negligible. In the third embodiment, semiconductor switching element 9 is used for backflow prevention during lifespan determination, whereby the loss can be reduced as compared with in the first embodiment.

### Fourth Embodiment

### Characteristics of Fourth Embodiment

In the lifespan determination in the first embodiment, the discharge time period from when discharging of smoothing capacitor C4 is started to when voltage value Vc of smoothing capacitor C4 reaches determination value Vd is measured. In a fourth embodiment, a residual voltage of smoothing capacitor C4 when a prescribed time period Ts has elapsed from the start of discharging of smoothing capacitor C4 is measured. Then, it is determined whether the residual voltage is lower than a threshold voltage. The following provides a detailed description with reference to the drawings.

Since an exemplary hardware configuration of a power supply device according to the fourth embodiment is the same as that described with reference to FIGS. 1 to 4 in the first embodiment, description will not be repeated. In addition, the fourth embodiment can be combined with either the second or third embodiment.

### [Operation in Determination Mode]

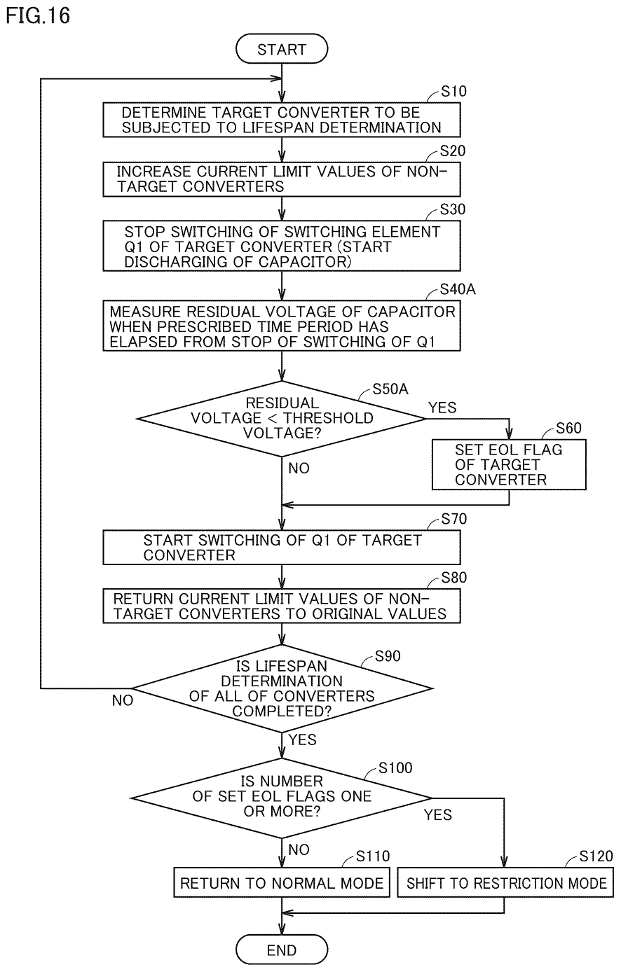

FIG. 16 is a flowchart showing a procedure of lifespan determination by a lifespan determination unit in the power supply device according to the fourth embodiment. The flowchart in FIG. 16 is different from the flowchart in FIG. 6 in that steps S40A and S50A are performed instead of steps S40 and S50. Since the other steps in FIG. 16 are the same as those in FIG. 6, the same or corresponding steps are denoted by the same reference characters and description will not be repeated.

Specifically, when lifespan determination unit 3 stops switching of semiconductor switching element Q1 of the target converter by outputting control signal S1 to power supply control circuit 4 in step S30, discharging of smoothing capacitor C4 is started.

In next step S40A, lifespan determination unit 3 measures an elapsed time period from the start of discharging of smoothing capacitor C4 by stopping switching of semiconductor switching element Q1. A counter built into lifespan determination unit 3 is, for example, used to measure the elapsed time period. Lifespan determination unit 3 measures, through voltage detection unit 5, the residual voltage of smoothing capacitor C4 when predetermined prescribed time period Ts has elapsed from the start of discharging of smoothing capacitor C4.

When the residual voltage of smoothing capacitor C4 is lower than the threshold voltage (YES in step S50A), lifespan determination unit 3 determines that the target converter has reached the end of life, and sets the EOL flag of the target converter (step S60). On the other hand, when the residual voltage of smoothing capacitor C4 is equal to or higher than the threshold voltage (NO in step S50A), lifespan determination unit 3 determines that the target converter has not yet reached the end of life, and does not set the EOL flag.

When the determination as to whether the target converter has reached the end of life is completed (steps S50A and S60), lifespan determination unit 3 transmits control signal S1 for starting switching of semiconductor switching element Q1 to power supply control circuit 4 in next step S70. Since the subsequent procedure is as described with reference to FIG. 6, description will not be repeated.

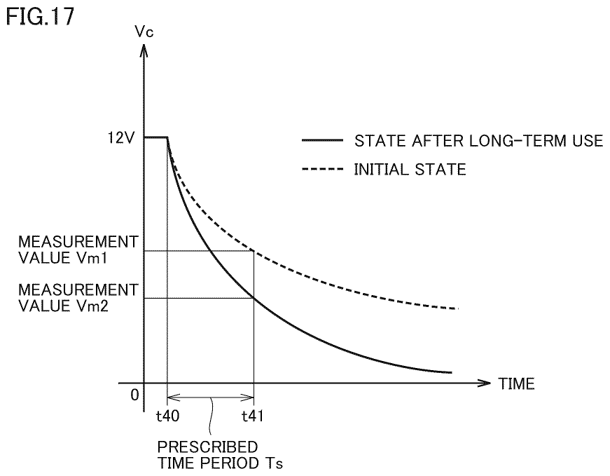

FIG. 17 is a diagram for illustrating a principle of lifespan determination of the converter in the power supply device according to the fourth embodiment. FIG. 17 shows an exemplary discharge curve in an initial state of the converter product (broken line) and an exemplary discharge curve in a state after long-term use (solid line). Let us assume that a rated value of voltage Vc of smoothing capacitor C4 in the normal mode is 12.0 V.

At time t40 in FIG. 17, lifespan determination unit 3 switches control signal S1 to be transmitted to power supply control circuit 4, thereby stopping switching of semiconductor switching element Q1. As a result, discharging of smoothing capacitor C4 is started.

Lifespan determination unit 3 measures, through voltage detection unit 5, voltage Vc of smoothing capacitor C4 at time t41 at which prescribed time period Ts has elapsed from the start of discharging of smoothing capacitor C4. In the initial state of the converter product, a measurement value of smoothing capacitor C4 at time t41 is Vm1. On the other hand, in the state after long-term use, a voltage measurement value of smoothing capacitor C4 at time t41 is Vm2, which is lower than voltage measurement value Vm1 in the initial state. When the voltage measurement value of smoothing capacitor C4 at time t41 is lower than the threshold voltage, lifespan determination unit 3 determines that the target converter has reached the end of life.

### Effects of Fourth Embodiment

The power supply device according to the fourth embodiment provides basically the same effects as those of the power supply device according to the first embodiment. Particularly, in the fourth embodiment, the residual voltage of smoothing capacitor C4 when prescribed time period Ts has elapsed from the start of discharging of smoothing capacitor C4 is measured, and thus, the time required for the lifespan determination of the target converter does not vary depending on a degree of deterioration of the converter. In contrast, in the first embodiment, the discharge time period to when voltage Vc of smoothing capacitor C4 reaches the determination value is measured, and thus, the time required for the lifespan determination of the target converter varies depending on a degree of deterioration of the converter. In this respect, the power supply device according to the fourth embodiment is different from the power supply device according to the first embodiment.

### Fifth Embodiment

### Characteristics of Fifth Embodiment

In the flowcharts in FIGS. 6 and 16 in the first and fourth embodiments, switching of semiconductor switching element Q1 is stopped at the time of lifespan determination of the target converter, and thus, the target value of output voltage Vo suddenly becomes zero. A power supply device according to a fifth embodiment is characterized in that output voltage Vo is temporarily decreased to a voltage lower than the value in the normal mode, and then, is decreased to zero at the time of lifespan determination of the target converter. The following provides a detailed description with reference to the drawings. The above-described characteristic of the fifth embodiment can be combined with any of the first to fourth embodiments.

### [Operation in Determination Mode]

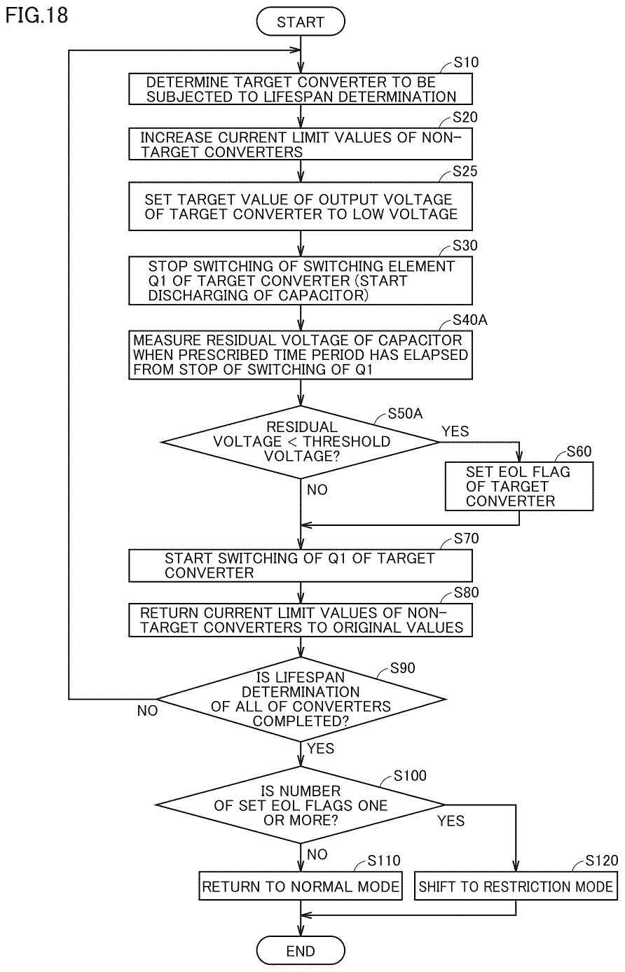

FIG. 18 is a flowchart showing a procedure of lifespan determination by a lifespan determination unit in the power supply device according to the fifth embodiment.

The flowchart in FIG. 18 is different from the flowchart in FIG. 16 in that step S25 is provided between step S20 and step S30. That is, lifespan determination unit 3 decreases the target value of output voltage Vo of the target converter to the voltage lower than the value in the normal mode in step S25 before stopping switching of semiconductor switching element Q1 of the target converter in step S30.

Since FIG. 18 is otherwise the same as FIG. 16, the same or corresponding steps are denoted by the same reference characters and description will not be repeated. Lifespan determination unit 3 may perform steps S40 and S50 in FIG. 6 instead of steps S40A and S50A in FIG. 18.

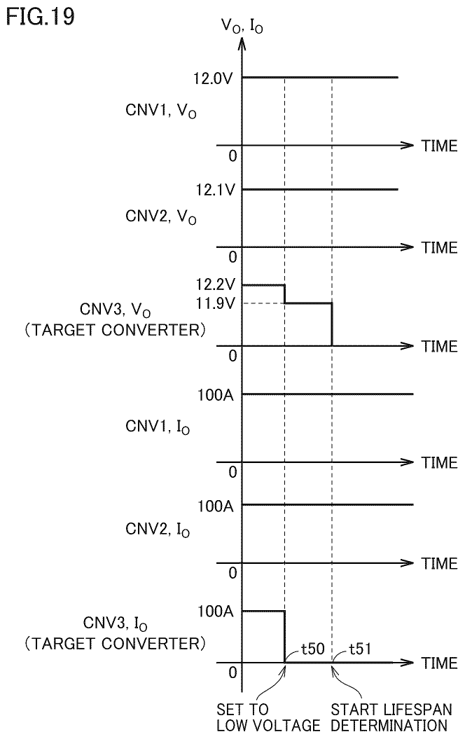

FIG. 19 is a timing chart showing an operation of each converter CNV constituting the power supply device according to the fifth embodiment. FIG. 19 shows the target values of output voltages Vo and the values of output currents Io of converters CNV1 to CNV3 constituting power supply device 1 in FIG. 1.

In the example shown in FIG. 19, in the normal mode before lifespan determination of converter CNV3 is executed, the target values of output voltages Vo of converters CNV1 to CNV3 are 12.0 V, 12.1 V and 12.2 V, respectively. In addition, output current Io of each of converters CNV1 to CNV3 is 100 A.

At time t50, lifespan determination unit 3 decreases the target value of output voltage Vo of converter CNV3 from 12.2 V to 11.9 V by changing control signal S1 to be transmitted to power supply control circuit 4 of target converter CNV3. Since power supply control circuit 4 is performing CVCC control, i.e., a constant voltage operation and a constant current operation to obtain the set target voltage values and target current values, output current Io of converter CNV3 becomes zero as a result of the above-described reduction in target value of output voltage Vo.

At next time t51, lifespan determination unit 3 outputs control signal S1 to power supply control circuit 4 of converter CNV3 to stop switching of semiconductor switching element Q1 of converter CNV3. As a result, the target value of output voltage Vo of converter CNV3 becomes zero and lifespan determination (i.e., discharging of smoothing capacitor C4) is started.

### Effects of Fifth Embodiment

As described above, in the power supply device according to the fifth embodiment, the target value of the output voltage of the target converter is decreased to the low voltage and the output current of the target converter is decreased to zero before starting the lifespan determination of the target converter. Thereafter, switching of semiconductor switching element Q1 is stopped to execute the lifespan determination of the target converter. Therefore, an abrupt change in output current Io does not occur at the start of the lifespan determination of the target converter, and thus, noise caused by the abrupt change does not occur, which allows a higher degree of accuracy of the lifespan determination.

### Sixth Embodiment

### Characteristics of Sixth Embodiment

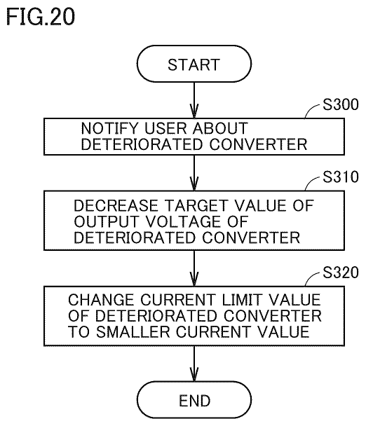

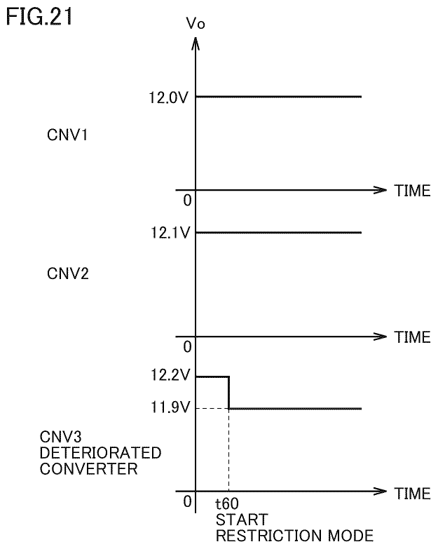

In the restriction mode of the power supply device according to the first embodiment, current limit value IL of the deteriorated converter is decreased and current limit values IL of the normal converters are increased, thereby prolonging the lifespan of the deteriorated converter. In the restriction mode of a power supply device according to a sixth embodiment, the target value of output voltage Vo of the deteriorated converter is decreased to be lower than the target values of output voltages Vo of the normal converters. A rate of operation of the deteriorated converter is thereby lowered. The following provides a detailed description with reference to FIGS. 20 and 21. The operation in the restriction mode in the sixth embodiment can be combined with any of the characteristics of the second to fifth embodiments.

### [Operation in Restriction Mode]

FIG. 20 is a flowchart showing an operation of a lifespan determination unit in the restriction mode in the power supply device according to the sixth embodiment.

In step S300 in FIG. 20, lifespan determination unit 3 notifies the user about the deteriorated converter determined as having reached the end of life in the determination mode, by causing the deteriorated converter to issue an alarm or the like.

In next step S310, lifespan determination unit 3 decreases the target value of output voltage Vo of the deteriorated converter to the lowest value among the values of converters CNVs constituting the power supply device, by changing control signal S1 to be transmitted to power supply control circuit 4 of the deteriorated converter.

In next step S320, lifespan determination unit 3 transmits setting signal S2 to current control unit 6 of the deteriorated converter so as to change current limit value IL of the deteriorated converter to a smaller current value. The restriction mode is continued until the deteriorated converter is replaced.

FIG. 21 is a timing chart showing a change in target value of the output voltage of each converter in the restriction mode in the power supply device according to the sixth embodiment. Let us assume that in FIG. 21, converter CNV3, of converters CNV1 to CNV3 constituting power supply device 1 in FIG. 1, is determined as having reached the end of life in the determination mode.

When the restriction mode is started at time t60, lifespan determination unit 3 decreases the target value of output voltage Vo of deteriorated converter CNV3 from 12.2 V to 11.9 V by changing control signal S1 to be transmitted to power supply control circuit 4 of deteriorated converter CNV3. 11.9 V is the lowest value among the target values of output voltages Vo of converters CNV1 to CNV3. An effect of this setting change will be described below.

Let us assume that a rated output current of each of converters CNV1 to CNV3 is 100 A. When a load current is 300 A, each of converters CNV1 to CNV3 outputs a current of 100 A. When the load current is 200 A, through the CVCC control by each power supply control circuit 4, each of converters CNV1 and CNV2 outputs output current Io of 100 A, and converter CNV3 does not output output current Io because the target value of output voltage Vo thereof is the lowest among converters CNV1 to CNV3. As the load current increases from 200 A, converter CNV3 outputs an amount of the load current corresponding to the increase.

As described above, given the CVCC operation by power supply control circuit 4 constituting each converter CNV, the rate of operation of the deteriorated converter can be lowered by setting the target value of output voltage Vo of the deteriorated converter to be lower than the target values of output voltages Vo of the other normal converters.

### Effects of Sixth Embodiment

As described above, in the power supply device according to the sixth embodiment, the target value of output voltage Vo of the deteriorated converter is set to be lower than the target values of output voltages Vo of the other normal converters in the restriction mode. Therefore, the load current is output only by the normal converters while the load current is low, and thus, the rate of operation of the deteriorated converter can be lowered. As a result, the deteriorated converter can be effectively used as an auxiliary power supply and the lifespan of the deteriorated converter can be prolonged until the deteriorated converter is replaced.

### Seventh Embodiment

### Characteristics of Seventh Embodiment

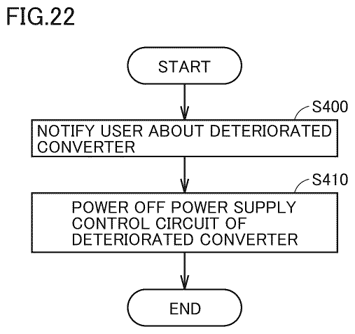

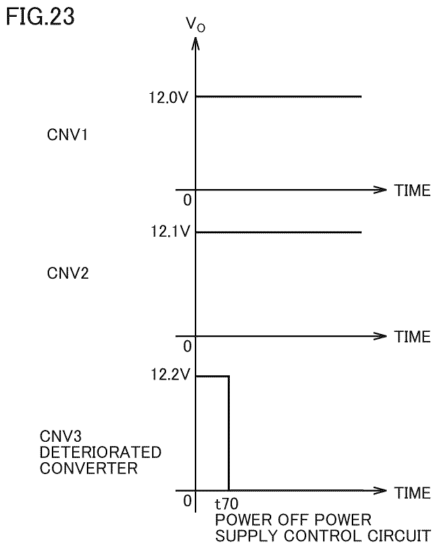

In a seventh embodiment, an operation different from the operation in the restriction mode described in each of the first and sixth embodiments will be described. Specifically, in a power supply device according to the seventh embodiment, power supply control circuit 4 of the deteriorated converter determined as having reached the end of life in the determination mode is powered off in the restriction mode. The following provides a specific description with reference to FIGS. 22 and 23. The operation in the restriction mode in the seventh embodiment can be combined with any of the characteristics of the second to fifth embodiments.

### [Operation in Restriction Mode]

FIG. 22 is a flowchart showing an operation of a lifespan determination unit in the restriction mode in the power supply device according to the seventh embodiment.

In step S400 in FIG. 22, lifespan determination unit 3 notifies the user about the deteriorated converter determined as having reached the end of life in the determination mode, by causing the deteriorated converter to issue an alarm or the like.

In next step S410, lifespan determination unit 3 turns off power supply to power supply control circuit 4 of the deteriorated converter by changing control signal S1 to be transmitted to power supply control circuit 4 of the deteriorated converter. As a result, the operation of the deteriorated converter stops, and thus, the target value of output voltage Vo and output current Io thereof both become zero. Therefore, the load current to be supplied to load 2 is supplied from converters CNV1 and CNV2 and is not supplied from converter CNV3, and thus, the load current is reduced as compared with in the normal mode.

FIG. 23 is a timing chart showing a change in target value of the output voltage of each converter in the restriction mode in the power supply device according to the seventh embodiment. Let us assume that in FIG. 23, converter CNV3, of converters CNV1 to CNV3 constituting power supply device 1 in FIG. 1, is determined as having reached the end of life in the determination mode.

When the restriction mode is started at time t70, lifespan determination unit 3 turns off power supply to power supply control circuit 4 of deteriorated converter CNV3 by changing control signal S1 to be transmitted to power supply control circuit 4 of deteriorated converter CNV3.

### Effects of Seventh Embodiment

In the power supply device according to the seventh embodiment, power supply control circuit 4 of the deteriorated converter is powered off, whereby the current is no longer output from the deteriorated converter. Therefore, a failure of the deteriorated converter can be prevented.

### Eighth Embodiment

### Characteristics of Eighth Embodiment

As described with reference to FIGS. 10, 20 and 22, in the restriction mode, lifespan determination unit 3 notifies the user or a maintenance person about the deteriorated converter determined as having reached the end of life in the determination mode, by causing the deteriorated converter to issue an alarm or the like. In an eighth embodiment, the method of notifying the user or the maintenance person will be described in more detail.

### [Configuration and Operation of Notification Device]

Each converter CNV constituting the power supply device includes a notification device for notifying the user or the maintenance person that converter CNV has reached the end of life. The user or the maintenance person notified by the notification device that the converter has reached the end of life replaces the deteriorated converter.

The notification device may include a light emitting component such as a light emitting diode (LED) and/or an acoustic component such as a speaker to notify the user or the like. These components are provided to allow the user or the maintenance person to identify the deteriorated converter. For example, the deteriorated converter is configured such that an error lamp such as an LED blinks on and off or a speaker makes a sound.

Furthermore, the notification device may include a wireless communication device. For example, the deteriorated converter provides notification of its own identification number to a personal digital assistant of the maintenance person or a terminal device such as a management computer through the wireless communication device. Alternatively, as an example, lifespan determination unit 3 having detected the end of life may transmit an alarm signal to a data server and cause the management computer to display an error dialog box by using the IoT technology.

The notification device is connected to lifespan determination unit 3 through wired communication or wireless communication. When lifespan determination unit 3 detects that certain converter CNV has reached the end of life, lifespan determination unit 3 sends an alarm signal (included in control signal S1 in FIG. 2) to the notification device included in this deteriorated converter so as to issue an alarm. The notification device having received the alarm signal makes the alarm known by light, sound or the like. An exemplary operation procedure of lifespan determination unit 3 and the notification device will be described below.

(1) Lifespan determination unit 3 having detected that certain converter CNV has reached the end of life transmits the alarm signal (included in control signal S1 in FIG. 2) to the notification device included in this deteriorated converter CNV having reached the end of life. Furthermore, lifespan determination unit 3 may transmit the alarm signal to the data server. The alarm signal may be transmitted a plurality of times.

(2) The notification device having received the alarm signal issues the alarm. For example, the notification device causes the LED to blink on and off, or causes the speaker to output a warning sound. The issuance of the alarm can be canceled by the user. The alarm may be issued periodically and an interval of the issuance of the alarm can be set by the user. When the data server receives the alarm signal from lifespan determination unit 3, the data server stores a reception history in a log file and notifies an administrator.

(3) When lifespan determination unit 3 detects removal of the deteriorated converter, lifespan determination unit 3 stops the transmission of the alarm signal. Lifespan determination unit 3 can detect removal of the deteriorated converter based on interruption of communication with converter CNV or the like.

### Effects of Eighth Embodiment

The deteriorated converter issues the alarm, which allows the user or the like to easily identify the deteriorated converter having reached the end of life. In addition, the alarm is actively issued when the end of life is detected, which makes it possible to avoid a situation in which converter CNV fails suddenly and the power supply device becomes inoperative.

### Ninth Embodiment

### Characteristics of Ninth Embodiment

In a ninth embodiment, a case of setting the threshold value for lifespan determination to multiple levels will be described.

### [Principle of Multi-Level Lifespan Determination]

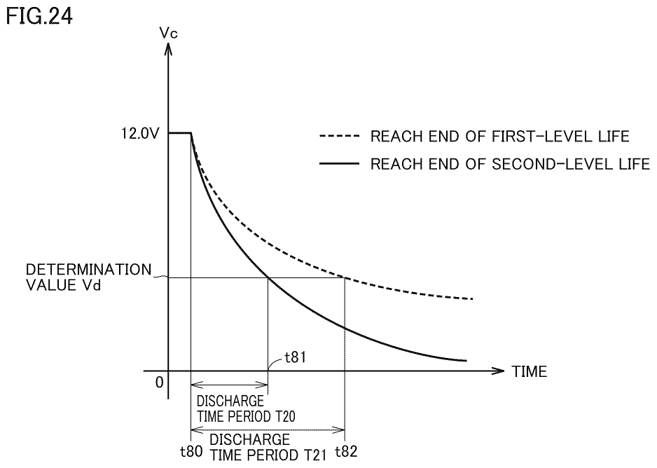

FIG. 24 is a diagram for illustrating a method of two-level lifespan determination. In FIG. 24, a discharge curve of smoothing capacitor C4 of converter CNV having reached the end of a first-level life is indicated by a broken line, and a discharge curve of smoothing capacitor C4 of converter CNV having reached the end of a second-level life is indicated by a solid line.

Referring to FIG. 24, discharging of smoothing capacitor C4 is started at time t80 and a discharge time period to when voltage Vc of smoothing capacitor C4 reaches determination value Vd is measured. In converter CNV having reached the end of the first-level life, a discharge time period T21 to when voltage Vc of smoothing capacitor C4 reaches determination value Vd (until time t82) is shorter than a first-level threshold time period. In converter CNV having reached the end of the second-level life, a discharge time period T20 to when voltage Vc of smoothing capacitor C4 reaches determination value Vd (until time t81) is shorter than a second-level threshold time period. The second-level threshold time period is shorter than the first-level threshold time period.

Unlike the case in FIG. 24, the threshold voltage may be set to multiple levels in the case of comparing, with the threshold voltage, a voltage value of smoothing capacitor C4 when prescribed time period Ts has elapsed from the start of discharging of smoothing capacitor C4 as described in the fourth embodiment. In this case, a second-level threshold voltage is smaller than a first-level threshold voltage.

The above-described threshold value (threshold time period or threshold voltage) may be set during manufacturing of power supply device 1, or may be arbitrarily settable by the user. A first-level alarm is issued when the first-level threshold value is reached, and a second-level alarm is issued when the second-level threshold value is reached.

### [Operation in Determination Mode]

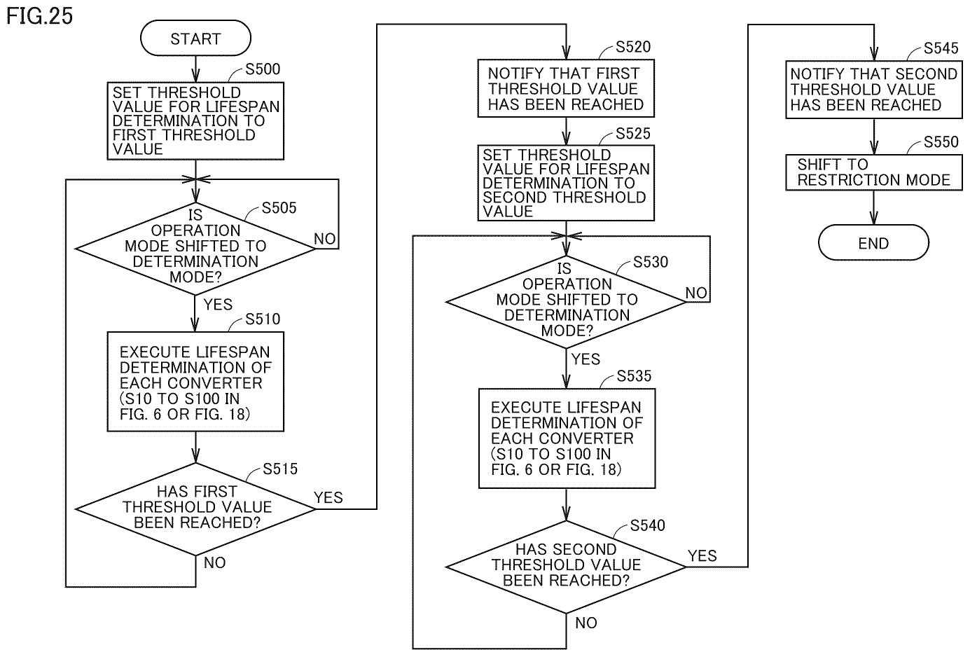

FIG. 25 is a flowchart showing a procedure of lifespan determination when the threshold value is set to two levels. In first step S500, lifespan determination unit 3 sets the threshold value (threshold time period or threshold voltage) for lifespan determination to a first threshold value.

When the operation mode is shifted from the normal mode to the determination mode (YES in step S505), lifespan determination unit 3 determines the end of life of each converter CNV constituting power supply device 1 in next step S510. The procedure in step S510 is the same as steps S10 to S100 in the flowchart shown in FIG. 6 or FIG. 18. Specifically, for each converter CNV, lifespan determination unit 3 determines whether the measured discharge time period of smoothing capacitor C4 or measured voltage Vc of smoothing capacitor C4 has reached the first threshold value (threshold time period or threshold voltage).

When the measurement value has not reached the first threshold value for any converters CNVs as a result of the above-described determination (NO in step S515), lifespan determination unit 3 returns the process to S505. On the other hand, when the measurement value has reached the first threshold value for any one of converters CNVs (YES in step S515), lifespan determination unit 3 determines that this converter has reached the end of life, and notifies the user, the maintenance person or the like about this converter as a deteriorated converter having reached the first threshold value (step S520). The user or the maintenance person may replace the deteriorated converter at this stage. Then, in next step S525, lifespan determination unit 3 sets the threshold value (threshold time period or threshold voltage) for lifespan determination to a second threshold value.

When the operation mode is shifted from the normal mode to the determination mode (YES in step S530), lifespan determination unit 3 determines the end of life of each converter CNV constituting power supply device 1 in next step S535. The procedure in step S535 is the same as steps S10 to S100 in the flowchart shown in FIG. 6 or FIG. 18. Specifically, for each converter CNV, lifespan determination unit 3 determines whether the measured discharge time period of smoothing capacitor C4 or measured voltage Vc of smoothing capacitor C4 has reached a second threshold value (threshold time period or threshold voltage).

When the measurement value has not reached the second threshold value for any converters CNVs as a result of the above-described determination (NO in step S540), lifespan determination unit 3 returns the process to S530. On the other hand, when the measurement value has reached the second threshold value for any one of converters CNVs (YES in step S540), lifespan determination unit 3 determines that this converter has reached the end of life, and notifies the user, the maintenance person or the like about this converter as a deteriorated converter having reached the second threshold value (step S545). Then, lifespan determination unit 3 shifts the operation mode to the restriction mode when the determination mode ends (step S550).

### Effects of Ninth Embodiment

As described above, in the power supply device according to the ninth embodiment, lifespan determination unit 3 sets the threshold value for lifespan determination to multiple levels, and causes the deteriorated converter to issue an alarm when the result of lifespan determination has reached the threshold value of each level. As a result, replacement converter CNV can be prepared in advance, which makes it possible to prevent a situation in which replacement converter CNV is not at hand when target converter CNV has reached the end of life. In addition, by setting the threshold value to multiple levels, target converter CNV can estimate the time remaining until the end of life.

### Tenth Embodiment

### Characteristics of Tenth Embodiment

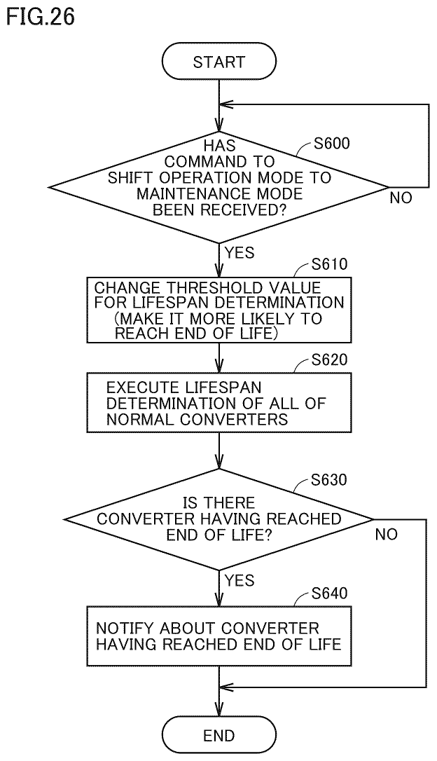

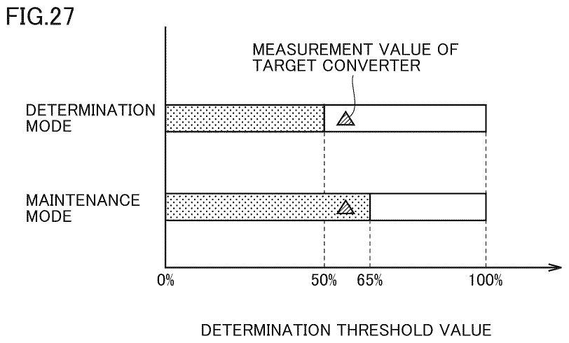

In a power supply device according to a tenth embodiment, a maintenance mode is provided as the operation mode in addition to the determination mode. In the maintenance mode, the threshold value for lifespan determination is changed to a value that makes it more likely to reach the end of life than in the determination mode. The purpose of providing the maintenance mode is to replace normal converter CNV close to the end of life together when the maintenance person replaces deteriorated converter CNV. The following provides a detailed description with reference to FIGS. 26 and 27.

### [Operation in Maintenance Mode]

FIG. 26 is a flowchart showing an operation procedure in the maintenance mode. In first step S600, lifespan determination unit 3 determines whether lifespan determination unit 3 has received a command to shift the operation mode to the maintenance mode. It is desirable that the shifting to the maintenance mode can be implemented only by the maintenance person and cannot normally be implemented by the general user. By way of example, a manual switch provided on the power supply device to shift the operation mode to the determination mode may be repeatedly pressed multiple times, or may be held down for a long time, or the like.

When lifespan determination unit 3 has received the command to shift the operation mode to the maintenance mode (YES in step S600), lifespan determination unit 3 changes the threshold value for lifespan determination to a value that makes it more likely to reach the end of life (S610). For example, when the discharge time period from when discharging of smoothing capacitor C4 is started to when voltage Vc of smoothing capacitor C4 reaches determination value Vd is measured as described in the first embodiment, lifespan determination unit 3 changes the threshold time period to a longer value. When voltage value Vc of smoothing capacitor C4 when prescribed time period Ts has elapsed from the start of discharging of smoothing capacitor C4 is measured as described in the fourth embodiment, lifespan determination unit 3 changes the threshold voltage to a higher value.

In next step S620, lifespan determination unit 3 executes lifespan determination of all of normal converters CNVs. When there is a converter having reached the end of life as a result of lifespan determination (YES in step S630), lifespan determination unit 3 notifies the maintenance person about the converter having reached the end of life (step S640).

### [as to Threshold Value for Lifespan Determination in Maintenance Mode]

FIG. 27 is a diagram for illustrating the threshold value for lifespan determination in the maintenance mode.

In FIG. 27, a value of 100% refers to a measurement value in lifespan determination in the initial state of converter CNV immediately after manufacturing. For example, when the discharge time period from when discharging of smoothing capacitor C4 is started to when voltage Vc of smoothing capacitor C4 reaches determination value Vd is measured as described in the first embodiment, the value of 100% refers to a measurement value of the discharge time period of converter CNV immediately after manufacturing. When voltage value Vc of smoothing capacitor C4 when prescribed time period Ts has elapsed from the start of discharging of smoothing capacitor C4 is measured as described in the fourth embodiment, the value of 100% refers to a measurement value of the voltage of converter CNV immediately after manufacturing.

As shown in FIG. 27, as an example, a determination threshold value in the determination mode is set to 50% of the measurement value in the initial state and a determination threshold value in the maintenance mode is set to 65% of the measurement value in the initial state. Therefore, in the determination mode, the target converter is determined as having reached the end of life when the measurement value is less than 50%, and in the maintenance mode, the target converter is determined as having reached the end of life when the measurement value is less than 65%.

Let us assume that the measurement value in lifespan determination of the target converter is between 50% and 65% of the measurement value in the initial state. In this case, although the target converter is not determined as having reached the end of life in the determination mode, the target converter is determined as having reached the end of life in the maintenance mode.

By providing the maintenance mode as described above, a converter close to the determination threshold value (50%) in the determination mode, i.e., converter CNV that will reach the end of life in a short time can be identified in advance. Therefore, in addition to the deteriorated converter that has already been determined as having reached the end of life in the determination mode, the converter close to the end of life can be replaced together during maintenance.

### Effects of Tenth Embodiment

As described above, in the power supply device according to the tenth embodiment, the maintenance mode is provided, whereby normal converter CNV close to the end of life that is expected to reach the end of life in a short time can be identified. Therefore, the normal converter close to the end of life can be replaced together during maintenance, which eliminates the need for repeated replacement of the converters in a short time, which leads to a reduction in cost.

### Eleventh Embodiment

### Characteristics of Eleventh Embodiment

In a power supply device according to an eleventh embodiment, lifespan determination unit 3 periodically shifts the operation mode from the normal mode to the determination mode and periodically executes lifespan determination of each converter CNV. When an ambient temperature of an electrolytic capacitor included in each converter CNV becomes high, lifespan determination unit 3 automatically increases a frequency of lifespan determination. Hereinafter, a state in which the frequency of execution of lifespan determination is higher than a normal state will be referred to as a high temperature mode, and a state in which the frequency of execution of lifespan determination is normal will be referred to as a normal temperature mode.

### [Configuration of Converter]

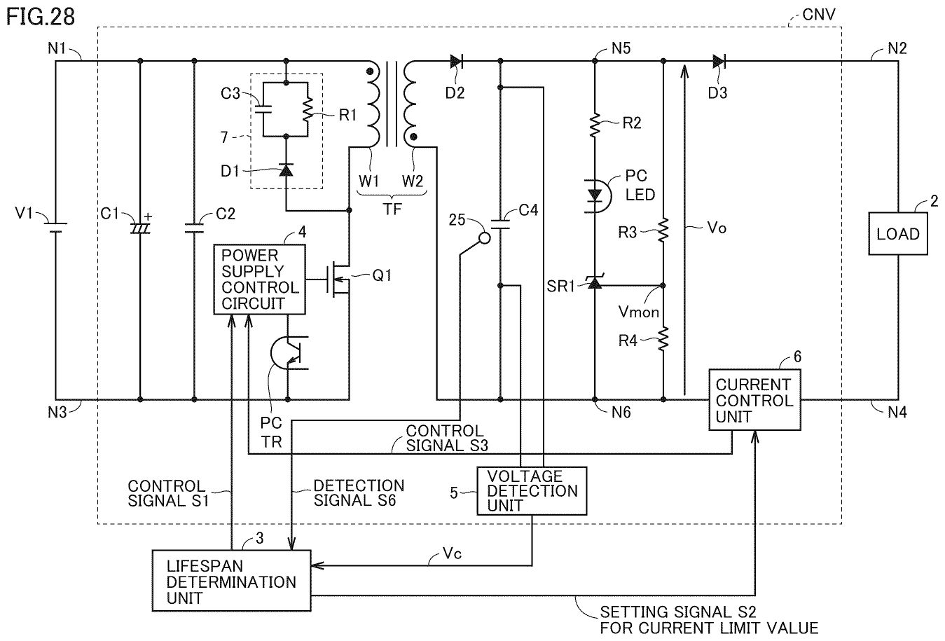

FIG. 28 is a circuit diagram showing an exemplary configuration of converter CNV in the power supply device according to the eleventh embodiment. Converter CNV in FIG. 28 is different from converter CNV in FIG. 2 in the first embodiment in that converter CNV in FIG. 28 further includes a temperature sensor 25 for detecting an ambient temperature of smoothing capacitor C4. Smoothing capacitor C4 is implemented by an electrolytic capacitor. Hereinafter, smoothing capacitor C4 will also be referred to as a smoothing electrolytic capacitor C4.

A thermocouple, a thermistor or the like can, for example, be used as temperature sensor 25. In order to detect the ambient temperature of smoothing capacitor C4, temperature sensor 25 may be directly attached to smoothing capacitor C4, or may be placed very close to smoothing capacitor C4.

A detection signal S6 from temperature sensor 25 is input to lifespan determination unit 3. Lifespan determination unit 3 determines whether the ambient temperature of smoothing electrolytic capacitor C4 detected by temperature sensor 25 exceeds a threshold temperature set by the user. When the ambient temperature exceeds the threshold temperature, lifespan determination unit 3 switches the operation mode from the normal temperature mode to the high temperature mode.

Since FIG. 28 is otherwise the same as FIG. 2, the same or corresponding portions are denoted by the same reference characters and description will not be repeated. FIG. 28 shows the example in which temperature sensor 25 and the high temperature mode are combined with converter CNV in FIG. 2 in the first embodiment. However, temperature sensor 25 and the high temperature mode in the present embodiment can also be combined with converters CNV in the other embodiments, instead of converter CNV in FIG. 2.

### [Relationship Between Ambient Temperature and Lifespan of Electrolytic Capacitor]

The electrolytic capacitor has such a tendency that the lifespan thereof becomes shorter as the ambient temperature thereof becomes higher. This phenomenon is related to evaporation of an electrolyte contained in the electrolytic capacitor. When an amount of the electrolyte decreases, a capacitance decreases, which results in an increase in equivalent series resistance (ESR), and thus, an increase in self-heating. As a result, the lifespan of the capacitor becomes shorter, and thus, the lifespan of the converter also becomes shorter.

The lifespan of the electrolytic capacitor caused by the ambient temperature is calculated in accordance with the following approximate formula called the Arrhenius Law:

$$L = {L}_{0} \times {2}^{( T - To ) / 10} . \qquad ( 1 )$$

In formula (1) above, L represents an estimated lifespan [hour], L₀ represents a lifespan [hour] at a rated temperature, T represents the rated temperature, and To represents an ambient temperature.

### [Relationship Between Ambient Temperature and Frequency of Lifespan Determination]

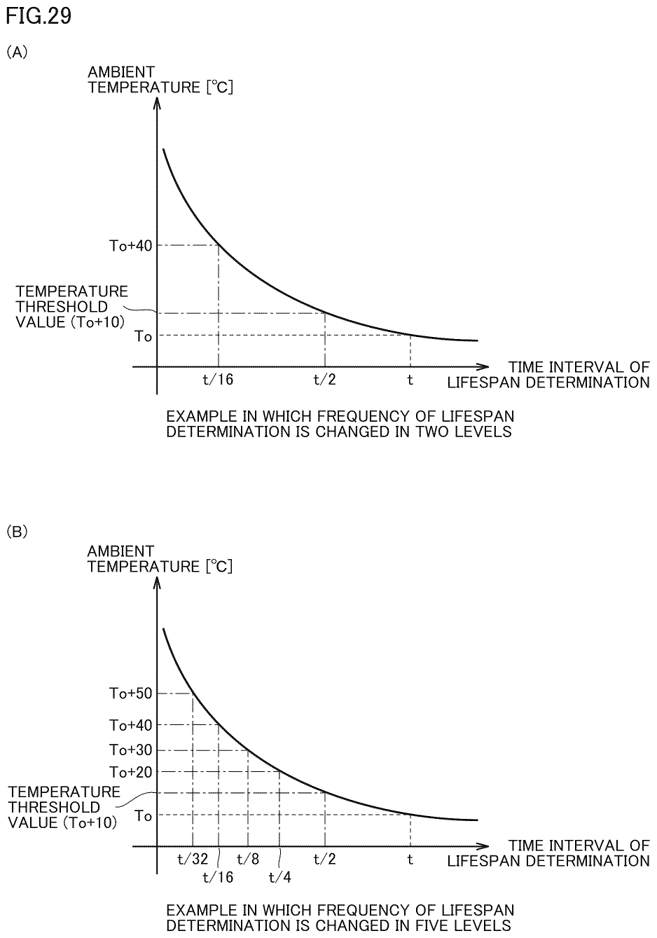

FIG. 29 is a diagram showing a relationship between the ambient temperature and the frequency of lifespan determination of the smoothing electrolytic capacitor. FIG. 29(A) shows an example in which the frequency of lifespan determination is changed in two levels, and FIG. 29(B) shows an example in which the frequency of lifespan determination is changed in five levels. In each of FIGS. 29(A) and 29(B), the vertical axis represents the ambient temperature of smoothing capacitor C4 and the horizontal axis represents a time interval at which lifespan determination is executed. A time interval at which lifespan determination is executed in the normal temperature mode is indicated by t, and a reference value of the ambient temperature is indicated by To [° C.]. Time interval t is set by the user.

Referring to FIG. 29(A), when the ambient temperature of smoothing electrolytic capacitor C4 becomes equal to or higher than a temperature threshold value (i.e., To+10 [° C.]), lifespan determination unit 3 changes the time interval at which lifespan determination is executed to t/2 (i.e., the frequency of determination is changed to a double). Furthermore, when the ambient temperature of smoothing capacitor C4 becomes equal to or higher than To+40 [° C.], lifespan determination unit 3 sets the time interval at which lifespan determination is executed to t/16 (i.e., the frequency of determination is set to be sixteen times as high as that in the normal temperature mode). As described above, it is desirable to set time interval t in accordance with the doubling-for-every-10° C. rule, which is the Arrhenius Law. The doubling-for-every−10° C. rule is an empirical rule that the speed of deterioration of a material is doubled, i.e., the lifespan is halved when the temperature rises by 10° C.

FIG. 29(B) is a diagram showing the case of changing the frequency of lifespan determination in five levels. As shown in FIG. 29(B), a time interval at which lifespan determination is executed in the normal temperature mode is indicated by t, and a reference value of the ambient temperature is indicated by To [° C.]. When the ambient temperature becomes equal to or higher than To+10, To+20, To+30, To+40, and To+50, lifespan determination unit 3 sets the time interval at which lifespan determination is executed to t/2, t/4, t/8, t/16, and t/32, respectively.

The examples in which the frequency of lifespan determination is changed in two levels and in five levels as described above are merely one example. Various examples in which the frequency of lifespan determination is changed in, for example, three levels, in six levels or the like are conceivable.

Generally, in the case of a power supply device such as an AC/DC converter, when an ambient temperature of an electrolytic capacitor becomes equal to or higher than 70 to 100° C., determination of high temperature tends to be made. Although a standard operating temperature range of the device varies depending on a product, the standard operating temperature range is −10° C. to 65° C. as an example.

### [Operation of Lifespan Determination Unit Based on Ambient Temperature]

In the normal temperature mode, lifespan determination unit 3 shifts the operation mode to the determination mode at every time interval t set by the user, and executes lifespan determination of smoothing electrolytic capacitor C4. Lifespan determination unit 3 shifts the operation mode to the high temperature mode based on the ambient temperature of smoothing electrolytic capacitor C4 becoming equal to or higher than the temperature threshold value. Lifespan determination unit 3 executes lifespan determination of smoothing electrolytic capacitor C4 at a time point of shifting to the high temperature mode, or at a time point of a lapse of a predetermined time period since shifting to the high temperature mode, or at a time point of a lapse of a changed time interval (e.g., t/2) since the previous execution of lifespan determination. Thereafter, lifespan determination unit 3 executes lifespan determination of smoothing electrolytic capacitor C4 at every changed time interval (e.g., t/2, t/4, . . . ) corresponding to the ambient temperature of smoothing electrolytic capacitor C4.

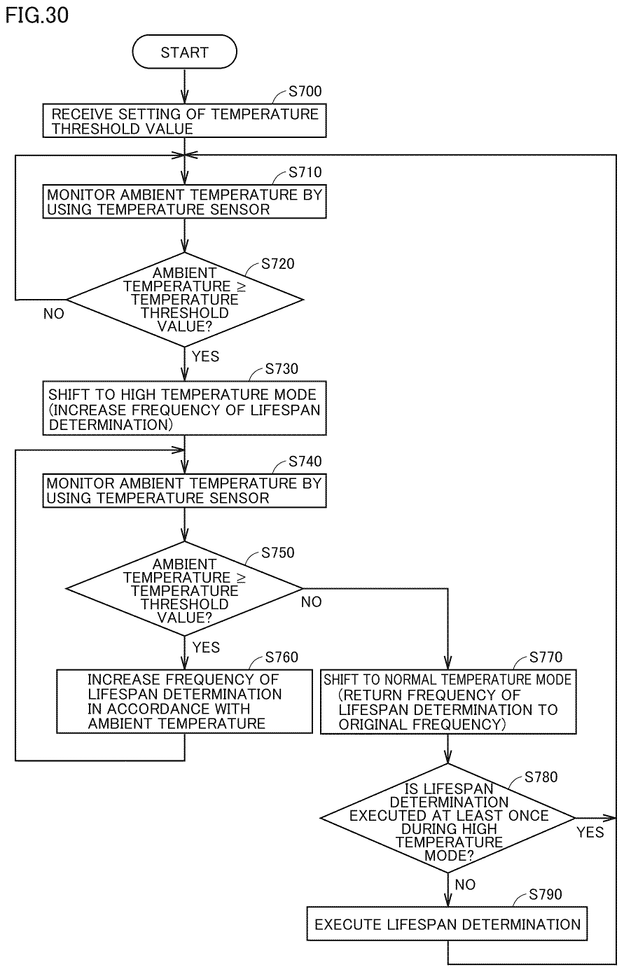

When the ambient temperature of smoothing electrolytic capacitor C4 falls below the temperature threshold value, lifespan determination unit 3 returns the operation mode from the high temperature mode to the normal temperature mode. In this case, when the operation mode is returned to the normal temperature mode before the first lifespan determination is executed after the operation mode is shifted to the high temperature mode (i.e., when lifespan determination is never executed during the high temperature mode), lifespan determination unit 3 executes lifespan determination of smoothing electrolytic capacitor C4 simultaneously with shifting to the normal temperature mode, in order to grasp a degree of deterioration of smoothing electrolytic capacitor C4. An operation of lifespan determination unit 3 in the eleventh embodiment will be described in more detail below with reference to FIG. 30.

FIG. 30 is a flowchart showing a procedure of changing the frequency of execution of lifespan determination in accordance with the ambient temperature of the smoothing electrolytic capacitor.

Referring to FIG. 30, in step S700 in the normal temperature mode, lifespan determination unit 3 receives a setting of the temperature threshold value from the user.

In next step S710, lifespan determination unit 3 monitors the ambient temperature of smoothing electrolytic capacitor C4 by using temperature sensor 25. In next step S720, lifespan determination unit 3 determines whether the ambient temperature detected by temperature sensor 25 is equal to or higher than the temperature threshold value set by the user. When the ambient temperature is lower than the temperature threshold value (NO in step S720), lifespan determination unit 3 returns the process to step S710 and continues to monitor the ambient temperature of smoothing electrolytic capacitor C4.

On the other hand, when the ambient temperature is equal to or higher than the temperature threshold value (YES in step S720), lifespan determination unit 3 moves the process to step S730. In step S730, lifespan determination unit 3 shifts the operation mode from the normal temperature mode to the high temperature mode. In the high temperature mode, the frequency of execution of lifespan determination is increased.

In next step S740, lifespan determination unit 3 monitors the ambient temperature of smoothing electrolytic capacitor C4 by using temperature sensor 25. In next step S750, lifespan determination unit 3 determines whether the ambient temperature detected by temperature sensor 25 is equal to or higher than the temperature threshold value. When the ambient temperature is equal to or higher than the temperature threshold value, the high temperature mode is continued. In this case, lifespan determination unit 3 may further increase the frequency of lifespan determination in accordance with the ambient temperature (step S760). Thereafter, lifespan determination unit 3 returns the process to step S740 and continues to monitor the ambient temperature of smoothing electrolytic capacitor C4.

On the other hand, when the ambient temperature is lower than the temperature threshold value (NO in step S750), lifespan determination unit 3 moves the process to step S770. In step S770, lifespan determination unit 3 returns the operation mode from the high temperature mode to the normal temperature mode. In the normal temperature mode, the frequency of execution of lifespan determination is decreased to the original frequency.

At the time point of shifting to the normal temperature mode, lifespan determination unit 3 determines whether lifespan determination is executed at least once during the high temperature mode from when the operation mode is shifted to the high temperature mode to when the operation mode is returned to the normal temperature mode (step S780). When lifespan determination is never executed during the high temperature mode (NO in step S780), lifespan determination unit 3 executes lifespan determination simultaneously with shifting to the normal temperature mode, in order to grasp the degree of degradation of smoothing electrolytic capacitor C4 caused by the temporary high temperature environment (step S790). Thereafter, the process is returned to first step S710.

### Effects of Eleventh Embodiment

As described above, according to the eleventh embodiment, even if the ambient temperature of the converter and the electrolytic capacitor becomes higher and thus the product lifespan of the converter becomes shorter, reaching of the end of life can be detected at an early stage by increasing the frequency of execution of lifespan determination. As a result, the maintenance work such as replacement of the converter can be performed at an early stage before a severe failure occurs, which makes it possible to avoid a failure due to the end of life during continuous operation in the high temperature environment. The technique according to the present embodiment is applicable to any product as long as the Arrhenius Law is applicable to the product.

Hereinafter, aspects of the present disclosure will be described collectively as additional notes.

### (Additional Note 1)

A power supply device comprising:
a plurality of converters connected in parallel with each other between an input node and an output node; and
a lifespan determination unit, wherein
the power supply device has a normal mode, a determination mode and a restriction mode as operation modes,
in the determination mode, the lifespan determination unit stops an operation of a target converter to be subjected to lifespan determination, while keeping the other converters in operation, and determines whether the target converter has reached an end of life based on a degree of decrease in voltage caused by discharging of a smoothing capacitor of the target converter,
when the lifespan determination unit determines in the determination mode that no converters have reached the end of life, the lifespan determination unit shifts the operation mode to the normal mode, the normal mode being a mode of operating the plurality of converters without output restriction, and
when there is a deteriorated converter having reached the end of life in the determination mode, the lifespan determination unit shifts the operation mode to the restriction mode, the restriction mode being a mode of restricting an output of the deteriorated converter.

### (Additional Note 2)

The power supply device according to Additional Note 1, wherein
each of the plurality of converters includes:
a first semiconductor switching element;
a power supply control circuit to control switching of the first semiconductor switching element;
a reactor or a transformer to store energy in response to a switching operation of the first semiconductor switching element;
the smoothing capacitor connected between the output node and the reactor or the transformer; and
a backflow prevention element connected between the smoothing capacitor and the output node to prevent a current from flowing into the smoothing capacitor of the target converter from an operating converter in the determination mode, and
in the determination mode, the power supply control circuit stops the switching operation of the first semiconductor switching element in accordance with a command from the lifespan determination unit.

### (Additional Note 3)

The power supply device according to Additional Note 2, wherein
in the determination mode, the lifespan determination unit measures a discharge time period, and when the discharge time period is shorter than a threshold time period, the lifespan determination unit determines that the target converter has reached the end of life, the discharge time period being a time period from when discharging of the smoothing capacitor is started by stopping the switching operation of the first semiconductor switching element of the target converter to when a voltage of the smoothing capacitor reaches a determination value.

### (Additional Note 4)

The power supply device according to Additional Note 3, wherein
the threshold time period is set to a plurality of levels.

### (Additional Note 5)

The power supply device according to Additional Note 2, wherein
in the determination mode, the lifespan determination unit measures a residual voltage of the smoothing capacitor, and when the residual voltage is smaller than a threshold voltage, the lifespan determination unit determines that the target converter has reached the end of life, the residual voltage being a voltage when a prescribed time period has elapsed from start of discharging of the smoothing capacitor by stopping the switching operation of the first semiconductor switching element of the target converter.

### (Additional Note 6)

The power supply device according to Additional Note 5, wherein the threshold voltage is set to a plurality of levels.

### (Additional Note 7)

The power supply device according to any one of Additional Notes 2 to 6, wherein
each of the plurality of converters further includes:
a discharge circuit connected in parallel with the smoothing capacitor, wherein
the discharge circuit includes a resistance element and a switch connected in series with each other, and
in the determination mode, the lifespan determination unit stops the switching operation of the first semiconductor switching element of the target converter and switches the switch of the discharge circuit from OFF to ON.

### (Additional Note 8)

The power supply device according to any one of Additional Notes 2 to 7, wherein
the backflow prevention element includes a second semiconductor switching element, and
in the determination mode, the lifespan determination unit stops the switching operation of the first semiconductor switching element of the target converter and switches the second semiconductor switching element from ON to OFF.

### (Additional Note 9)

The power supply device according to any one of Additional Notes 2 to 7, wherein
the backflow prevention element includes a diode.

### (Additional Note 10)

The power supply device according to any one of Additional Notes 2 to 9, wherein
in the determination mode, the lifespan determination unit decreases a target value of an output voltage of the target converter to be lower than a value in the normal mode, before stopping the switching operation of the first semiconductor switching element of the target converter.

### (Additional Note 11)

The power supply device according to any one of Additional Notes 2 to 10, wherein
the restricting the output of the deteriorated converter in the restriction mode includes setting a target value of an output voltage of the deteriorated converter to a voltage lower than target values of output voltages of the other converters.

### (Additional Note 12)

The power supply device according to any one of Additional Notes 2 to 10, wherein
the restricting the output of the deteriorated converter in the restriction mode includes turning off an operation power supply for the power supply control circuit of the deteriorated converter.

### (Additional Note 13)

The power supply device according to any one of Additional Notes 2 to 10, wherein
in each of the plurality of converters, the power supply control circuit controls switching of the first semiconductor switching element such that an output current of the converter does not exceed a current limit value, and
in the restriction mode, the lifespan determination unit decreases the current limit value of the deteriorated converter and increases the current limit values of the other converters.

### (Additional Note 14)

The power supply device according to any one of Additional Notes 1 to 13, wherein
in the restriction mode, the lifespan determination unit notifies a user about the deteriorated converter.

### (Additional Note 15)

The power supply device according to any one of Additional Notes 1 to 14, wherein
the power supply device further has a maintenance mode as the operation mode,
in the maintenance mode, the lifespan determination unit stops the operation of the target converter to be subjected to lifespan determination, while keeping the other converters in operation, and determines whether the target converter has reached the end of life based on the degree of decrease in voltage caused by discharging of the smoothing capacitor of the target converter, and
in the maintenance mode, the lifespan determination unit determines the degree of decrease in voltage of the smoothing capacitor such that the lifespan determination unit may determine that the target converter has reached the end of life even when the lifespan determination unit does not determine in the determination mode that the target converter has reached the end of life.

### (Additional Note 16)

The power supply device according to any one of Additional Notes 1 to 15, wherein
the lifespan determination unit periodically executes lifespan determination of the plurality of converters by periodically shifting the operation mode from the normal mode to the determination mode,
each of the plurality of converters includes a temperature sensor to measure an ambient temperature of the smoothing capacitor, and
when the ambient temperature of the smoothing capacitor becomes equal to or higher than a temperature threshold value, the lifespan determination unit increases a frequency of execution of the lifespan determination.

It should be understood that the embodiments disclosed herein are illustrative and non-restrictive in every respect. The scope of the present application is defined by the terms of the claims, rather than the description above, and is intended to include any modifications within the scope and meaning equivalent to the terms of the claims.

### REFERENCE SIGNS LIST

1 power supply device; 2 load; 3 lifespan determination unit; 4 power supply control circuit; 5 voltage detection unit; 6 current control unit; 6A current detection unit; 6B storage unit; 6C comparator; 7 snubber circuit; 8 discharge circuit; 9 second semiconductor switching element; 20 normal mode; 21 determination mode; 22 restriction mode; 25 temperature sensor; C1 power supply smoothing capacitor; C2 main circuit capacitor; C3 capacitor; C4 smoothing capacitor; CNV, CNV1 to CNV3 converter; D1 to D3 diode; EA error amplifier; IL current limit value; IS current sensor; Idc discharge path; Io output current; N1 input node; N2 output node; N3, N4 ground node; N5, N6 intermediate node; PC photocoupler; Q1 first semiconductor switching element; Q2 MOSFET; R1 to R5 resistance element; S1, S3, S4, S5 control signal; S2 setting signal; SR1 shunt regulator; TF transformer; TR phototransistor; TR1 transistor; Ts prescribed time period; V1 external DC power supply; V2 external AC power supply; Vc capacitor voltage; Vd determination value; Vo output voltage; Vref reference voltage; W1 primary winding; W2 secondary winding.

1-16. (canceled)

17. A power supply device comprising:
a plurality of converters connected in parallel with each other between an input node and an output node; and
a lifespan determination unit, wherein
the lifespan determination unit determines whether a target converter of the plurality of converters, which is to be subjected to lifespan determination, has reached an end of life based on a degree of decrease in voltage caused by discharging of a smoothing capacitor of the target converter.

18. The power supply device according to claim 17, wherein the lifespan determination unit stops an operation of the target converter while keeping the other converters in operation, and determines whether the target converter has reached the end of life.

19. The power supply device according to claim 18, wherein
the power supply device has a determination mode and a restriction mode as operation modes, and
in the determination mode, the lifespan determination unit determines whether the target converter has reached the end of life, and when the target converter is a deteriorated converter having reached the end of life, the lifespan determination unit shifts the operation mode to the restriction mode, the restriction mode being a mode of restricting an output of the deteriorated converter.

20. The power supply device according to claim 19, wherein
the power supply device further has a normal mode as the operation modes, and
when the lifespan determination unit determines in the determination mode that no converters have reached the end of life, the lifespan determination unit shifts the operation mode to the normal mode, the normal mode being a mode of operating the plurality of converters without output restriction.

21. The power supply device according to claim 20, wherein
each of the plurality of converters includes:
a first semiconductor switching element;
a power supply control circuit to control switching of the first semiconductor switching element;
a reactor or a transformer to store energy in response to a switching operation of the first semiconductor switching element;
the smoothing capacitor connected between the output node and the reactor or the transformer; and
a backflow prevention element connected between the smoothing capacitor and the output node to prevent a current from flowing into the smoothing capacitor of the target converter from an operating converter in the determination mode, and
in the determination mode, the power supply control circuit stops the switching operation of the first semiconductor switching element in accordance with a command from the lifespan determination unit.

22. The power supply device according to claim 21, wherein
in the determination mode, the lifespan determination unit measures a discharge time period, and when the discharge time period is shorter than a threshold time period, the lifespan determination unit determines that the target converter has reached the end of life, the discharge time period being a time period from when discharging of the smoothing capacitor is started by stopping the switching operation of the first semiconductor switching element of the target converter to when a voltage of the smoothing capacitor reaches a determination value.

23. The power supply device according to claim 22, wherein
the threshold time period is set to a plurality of levels.

24. The power supply device according to claim 21, wherein
in the determination mode, the lifespan determination unit measures a residual voltage of the smoothing capacitor, and when the residual voltage is smaller than a threshold voltage, the lifespan determination unit determines that the target converter has reached the end of life, the residual voltage being a voltage when a prescribed time period has elapsed from start of discharging of the smoothing capacitor by stopping the switching operation of the first semiconductor switching element of the target converter.

25. The power supply device according to claim 24, wherein
the threshold voltage is set to a plurality of levels.

26. The power supply device according to claim 21, wherein
each of the plurality of converters further includes:
a discharge circuit connected in parallel with the smoothing capacitor, wherein
the discharge circuit includes a resistance element and a switch connected in series with each other, and
in the determination mode, the lifespan determination unit stops the switching operation of the first semiconductor switching element of the target converter and switches the switch of the discharge circuit from OFF to ON.

27. The power supply device according to claim 21, wherein
the backflow prevention element includes a second semiconductor switching element, and
in the determination mode, the lifespan determination unit stops the switching operation of the first semiconductor switching element of the target converter and switches the second semiconductor switching element from ON to OFF.

28. The power supply device according to claim 21, wherein
the backflow prevention element includes a diode.

29. The power supply device according to claim 21, wherein
in the determination mode, the lifespan determination unit decreases a target value of an output voltage of the target converter to be lower than a value in the normal mode, before stopping the switching operation of the first semiconductor switching element of the target converter.

30. The power supply device according to claim 21, wherein
the restricting the output of the deteriorated converter in the restriction mode includes setting a target value of an output voltage of the deteriorated converter to a voltage lower than target values of output voltages of the other converters.

31. The power supply device according to claim 21, wherein
the restricting the output of the deteriorated converter in the restriction mode includes turning off an operation power supply for the power supply control circuit of the deteriorated converter.

32. The power supply device according to claim 21, wherein
in each of the plurality of converters, the power supply control circuit controls switching of the first semiconductor switching element such that an output current of the converter does not exceed a current limit value, and
in the restriction mode, the lifespan determination unit decreases the current limit value of the deteriorated converter and increases the current limit values of the other converters.

33. The power supply device according to claim 19, wherein
in the restriction mode, the lifespan determination unit notifies a user about the deteriorated converter.

34. The power supply device according to claim 20, wherein
the power supply device further has a maintenance mode as the operation mode,
in the maintenance mode, the lifespan determination unit stops the operation of the target converter to be subjected to lifespan determination, while keeping the other converters in operation, and determines whether the target converter has reached the end of life based on the degree of decrease in voltage caused by discharging of the smoothing capacitor of the target converter, and
in the maintenance mode, the lifespan determination unit determines the degree of decrease in voltage of the smoothing capacitor such that the lifespan determination unit may determine that the target converter has reached the end of life even when the lifespan determination unit does not determine in the determination mode that the target converter has reached the end of life.

35. The power supply device according to claim 34, wherein
the lifespan determination unit periodically executes lifespan determination of the plurality of converters by periodically shifting the operation mode from the normal mode to the determination mode,
each of the plurality of converters includes a temperature sensor to measure an ambient temperature of the smoothing capacitor, and
when the ambient temperature of the smoothing capacitor becomes equal to or higher than a temperature threshold value, the lifespan determination unit increases a frequency of execution of the lifespan determination.
